(19) United States
(12) Patent Application Publication
(10) Pub. No.: US 2026/0231746 A1
(43) Pub. Date: Aug. 6, 2026

(54) SEMICONDUCTOR PACKAGE

(71) Applicant: SAMSUNG ELECTRONICS CO., LTD., Suwon-si (KR)

(72) Inventors: Hyunsoo CHUNG, Suwon-si (KR); Won-Young KIM, Suwon-si (KR)

(73) Assignee: SAMSUNG ELECTRONICS CO., LTD., Suwon-si (KR)

(21) Appl. No.: 19/301,578

(22) Filed: Aug. 15, 2025

(30) Foreign Application Priority Data
Feb. 4, 2025 (KR) 10-2025-0013735

(51) Int. Cl. H01L 23/00; H01L 21/56; H01L 23/31; H01L 23/48; H01L 23/538; H01L 25/16; H10B 80/00; H10D 80/30

(52) U.S. Cl. CPC H10W 20/20; H10B 80/00; H10D 80/30; H10W 70/611; H10W 70/65; H10W 74/117; H10W 74/141; H10W 90/00; H10W 90/401; H10W 72/227; H10W 72/926; H10W 72/9445; H10W 74/016; H10W 80/312; H10W 80/327; H10W 90/724; H10W 90/792; H10W 90/794

(57) ABSTRACT

Provided is a semiconductor package including an interposer including a first surface and a second surface opposite to the first surface, a first semiconductor chip including a first semiconductor substrate including a front side facing the first surface of the interposer in a first direction, a plurality of first bonding pads on a back side that is opposite to the front side of the first semiconductor substrate, and a first bonding insulation layer surrounding the plurality of first bonding pads, a second semiconductor chip including a second semiconductor substrate including a back side facing the back side of the first semiconductor substrate in the first direction, and a passive device that is included in the second semiconductor substrate and is electrically connected to the first semiconductor chip.

### CROSS-REFERENCE TO RELATED APPLICATIONS

This application claims the benefit of Korean Patent Application No. 10-2025-0013735, filed on Feb. 4, 2025, in the Korean Intellectual Property Office, the disclosure of which is incorporated herein by reference in its entirety.

### BACKGROUND

### 1. Field of the Invention

Example embodiments relate to a semiconductor package.

### 2. Description of the Related Art

The semiconductor industry is pursuing increased integration density so that more passive or active devices can be integrated into a given area. Accordingly, included in a semiconductor package is high performance circuit in which the integration of semiconductor chips is increased and digital signals are processed at high speed along the same direction.

With respect to the semiconductor package including the high performance circuits, power integrity (PI) characteristics is important, and there is a need to develop new semiconductor package technologies that can improve the PI of semiconductor packages containing high performance circuits.

### SUMMARY

An aspect provides a semiconductor package in which the PI of semiconductor package containing high performance circuit is improved.

The technical tasks to be achieved by the present example embodiments are not limited to the technical tasks described above, and other technical tasks may be inferred from the following example embodiments by those skilled in the art.

According to an aspect, there is provided a semiconductor package including an interposer including a first surface and a second surface opposite to the first surface, a first semiconductor chip including a first semiconductor substrate including a front side facing the first surface of the interposer in a first direction, a plurality of first bonding pads on a back side that is opposite to the front side of the first semiconductor substrate, and a first bonding insulation layer surrounding the plurality of first bonding pads, a second semiconductor chip including a second semiconductor substrate including a back side facing the back side of the first semiconductor substrate in the first direction, a passive device that is included in the second semiconductor substrate and is electrically connected to the first semiconductor chip, a plurality of second bonding pads on the back side of the second semiconductor substrate, and a second bonding insulation layer surrounding the plurality of second bonding pads, and a plurality of conductive posts that are placed on a side surface of the first semiconductor chip and extending to the back side of the second semiconductor substrate to connect the interposer and the second semiconductor chip. At least one of the plurality of first bonding pads and at least one of the plurality of second bonding pads are directly bonded to each other, and a portion of the first bonding insulation layer and a portion of the second bonding insulation layer are directly bonded to each other.

According to an aspect, there is provided a semiconductor package including an interposer including an interposer substrate including a first surface and a second surface opposite to the first surface, a logic chip including a first semiconductor substrate that is spaced apart from the first surface of the interposer substrate and includes a back side facing the interposer, a first bonding pad on the back side of the first semiconductor substrate, and a first bonding insulation layer surrounding the first bonding pad, a passive device chip including a second semiconductor substrate including a back side facing the back side of the first semiconductor substrate in a first direction, a passive device included in the second semiconductor substrate and is electrically connected with the logic chip, a second bonding pad on the back side of the second semiconductor substrate, and a second bonding insulation layer surrounding the second bonding pad, a redistribution structure on a front side opposite to the back side of the first semiconductor substrate, and a plurality of conductive posts placed on a side surface of the logic chip in the redistribution structure and are configured to connect the redistribution structure and the passive device chip. The first bonding pad is directly bonded to the second bonding pad, and the first bonding insulation layer is directly bonded to the second bonding insulation layer.

According to an aspect, there is provided a semiconductor package including an interposer including an interposer substrate including a first surface and a second surface opposite to the first surface, and an interposer through electrode that penetrates the interposer substrate, a logic chip including a first semiconductor substrate including a front side facing the first surface of the interposer in a first direction, a plurality of first bonding pads on a back side that is opposite to the front side of the first semiconductor substrate, and a first bonding insulation layer surrounding the plurality of first bonding pads, a passive device chip including a second semiconductor substrate including a back side facing a back side of the first semiconductor substrate in the first direction, a passive device included in the second semiconductor substrate and connected with the logic chip, a plurality of second bonding pads on the back side of the second semiconductor substrate, and a second bonding insulation layer surrounding the plurality of second bonding pads, a plurality of conductive posts that are placed on a side surface of the logic chip on the back side of the second semiconductor substrate to connect the interposer and the passive device chip, one pair of stacked memory chip structures that are mounted on the second surface of the interposer and spaced apart from each other in a second direction intersecting the first direction, a redistribution structure on a front side opposite to the back side of the second semiconductor substrate, a first molding layer configured to seal the passive device chip and the plurality of conductive posts between the redistribution structure and the passive device chip, and a second molding layer configured to seal the one pair of stacked memory chip structures on the second surface of the interposer substrate. At least one of the plurality of first bonding pads and at least one of the plurality of second bonding pads are directly bonded to each other, and a portion of the first bonding insulation layer and a portion of the second bonding insulation layer are directly bonded to each other, and a width of the second semiconductor substrate in the second direction is greater than a width of the first semiconductor substrate in the second direction, and is equal to a width of the interposer substrate in the second direction.

According to an aspect, there is provided a method of manufacturing a semiconductor package, the method including preparing an interposer substrate including a first surface and a second surface opposite to the first surface, mounting a first semiconductor chip including a first bonding pad on the first surface of the interposer substrate and a first bonding insulation layer surrounding the first bonding pad, and forming a conductive post, forming a first molding layer configured to seal the first semiconductor chip and the conductive post, bonding a second semiconductor chip including a second bonding pad and a second bonding insulation layer surrounding the second bonding pad, to the first semiconductor chip. The bonding the second semiconductor chip to the first semiconductor chip includes that the first bonding pad and the second bonding pad are directly bonded to each other, and the first bonding insulation layer and the second bonding insulation layer are directly bonded to each other.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is a schematic plan view illustrating a semiconductor package according to an example embodiment;

FIG. 2 is a drawing illustrating a cross-section taken along line A-A′ of FIG. 1;

FIG. 3 is an enlarged view of the portion indicated as “CX1” in FIG. 2;

FIG. 4 is a schematic plan view illustrating a second bonding insulation layer illustrated in FIG. 2;

FIG. 5 is a cross-sectional view illustrating a semiconductor package according to another example embodiment;

FIG. 6 is a cross-sectional view illustrating a semiconductor package according to another example embodiment;

FIG. 7 is a cross-sectional view illustrating a semiconductor package according to another example embodiment;

FIG. 8 is an enlarged view of the portion indicated as “CX2” in FIG. 7;

FIG. 9 is a cross-sectional view illustrating a semiconductor package according to another example embodiment;

FIG. 10 is an enlarged view of the portion indicated as “CX3” in FIG. 9;

FIGS. 11A, 11B, 11C, 11D, 11E, 11F, 11G, 11H and FIG. 11I are cross-sectional views illustrating a process sequence for explaining a method of manufacturing a semiconductor package according to an example embodiment; and

FIGS. 12A, 12B, 12C, 12D, 12E, 12F, 12G, 12H, 12I and FIG. 12J are cross-sectional views illustrating a process sequence for explaining a method of manufacturing a semiconductor package according to an example embodiment.

### DETAILED DESCRIPTION

Hereinafter, example embodiments will be described in detail with reference to the attached drawings. The same reference numerals are used for identical elements in the drawings, and duplicate descriptions of these are omitted.

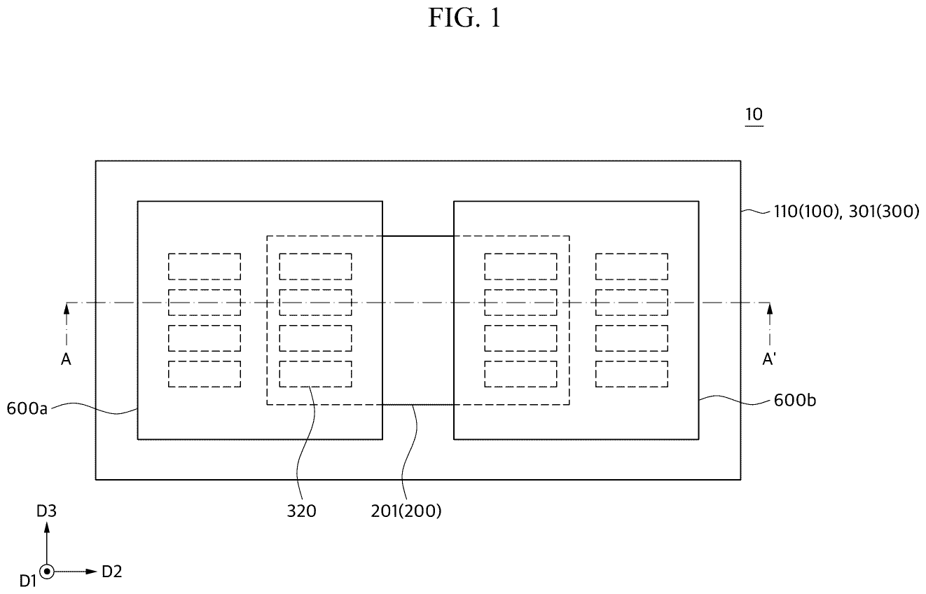

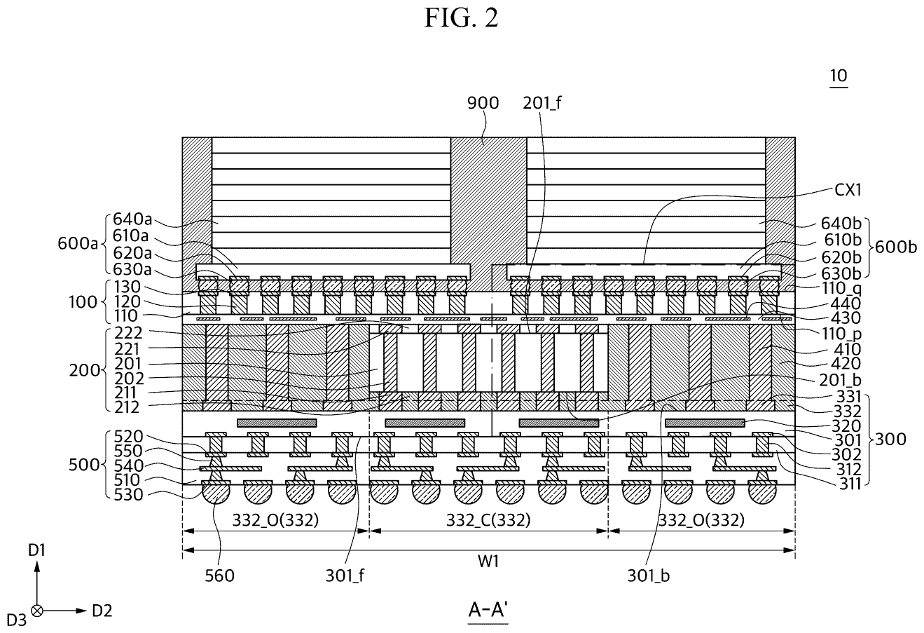

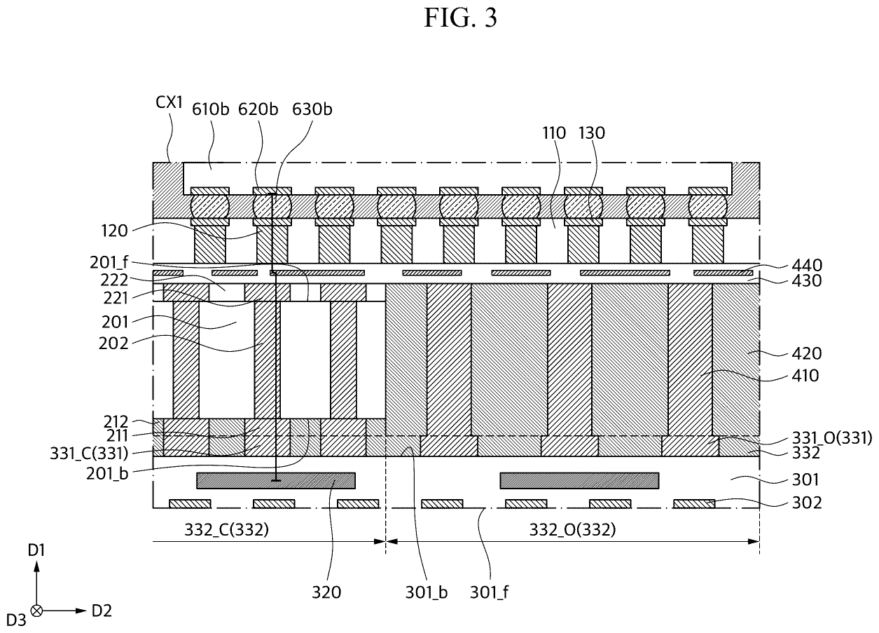

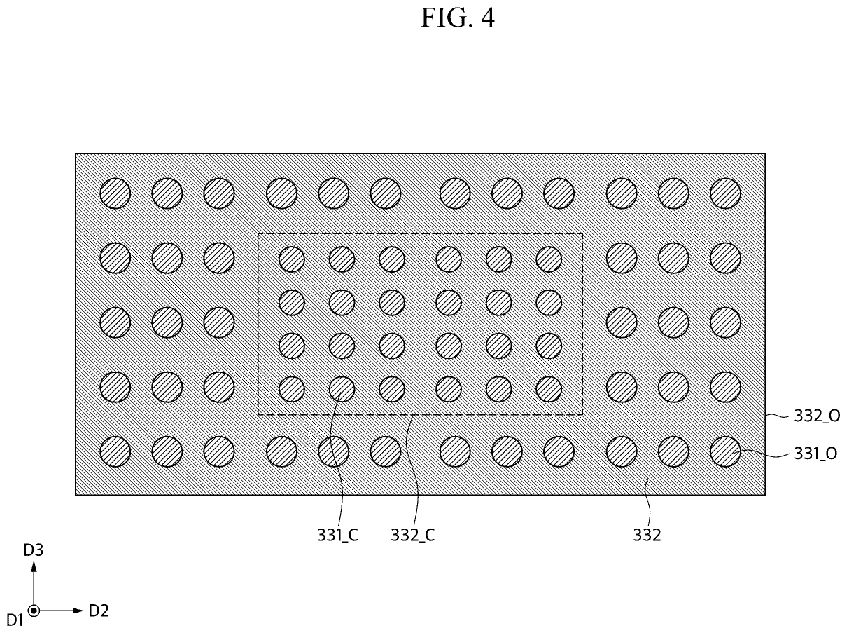

FIG. 1 is a schematic plan view illustrating a semiconductor package 10 according to an example embodiment. FIG. 2 is a drawing illustrating a cross-section taken along line A-A′ of FIG. 1. FIG. 3 is an enlarged view of the portion indicated as “CX1” in FIG. 2. FIG. 4 is a schematic plan view illustrating a second bonding insulation layer 332 illustrated in FIG. 2.

According to an example embodiment, the semiconductor package 10 may include an interposer 100, a first semiconductor chip 200, a second semiconductor chip 300, a conductive post 410, a first molding layer 420, a bonding film 430, and a conductive pattern 440.

According to an example embodiment, the interposer 100 may include an interposer substrate 110, an interposer through electrode 120, and an interposer pad 130. The interposer substrate 110 may provide a first surface 110_p and a second surface 110_q opposite to the first surface 110_p. The first surface 110_p and the second surface 110_q of the interposer substrate 110 are relatively large surfaces among the surfaces provided by the interposer substrate 110, and the second surface 110_q of the interposer substrate 110 may be a surface that provides a space on which semiconductor devices are mounted and electrically connected.

For example, the interposer substrate 110 may include a semiconductor material, for example, silicon, germanium and silicon-germanium or a group III-V compound semiconductor, for example, gallium phosphide (GaP), gallium arsenide (GaAs) or gallium antimonide (GaSb). According to some example embodiments, the interposer substrate 110 may be a silicon-on-insulator (SOI) substrate or a germanium-on-insulator (GOI) substrate.

In describing a semiconductor package according to example embodiments, the first direction D1 may refer to a direction intersecting the first surface 110_p of the interposer substrate 110, and may also refer to a direction in which the first semiconductor chip 200, the second semiconductor chip 300 and the interposer 100, which will be described later, are laminated to each other. Further, the second direction D2 may indicate a direction that intersects the first direction D1, and may also indicate a direction in which a pair of memory chip structures (a first memory chip structure 600a and a second memory chip structure 600b) to be described later are separated from each other. The third direction D3 may indicate a direction that intersects the first direction D1 and the second direction D2 at the same time. Further, in order to help understanding of the disclosure, the higher level along the first direction D1 is named the upper side, and the lower level along the first direction D1 is named the lower side.

According to an example embodiment, the interposer through electrode 120 may extend in the first direction D1 while penetrating at least a portion of the interposer substrate 110. The interposer pad 130 may be positioned so that its upper surface is exposed to the second surface 110_q of the interposer substrate 110. A plurality of interposer pads 130 may be provided, and the plurality of interposer pads 130 may be oriented in the second direction D2 and/or the third direction D3 with their upper surfaces exposed to the second surface 110_q of the interposer substrate 110. The plurality of interposer pads 130 may provide electrical connection terminals for electrically connecting a plurality of semiconductor devices mounted on the second surface 110_q of the interposer substrate 110 to the interposer 100. However, according to an example embodiment, the plurality of interposer pads 130 may not be arranged so as to expose only their upper surfaces to the second surface 110_q of the interposer substrate 110, but may be arranged on the second surface 110_q of the interposer substrate 110 so as to expose at least a portion of the upper surface and at least a portion of the side surface. For example, the interposer pad 130 may include at least one metal selected from tungsten (W), aluminum (Al) and copper (Cu).

According to an example embodiment, the upper surface of the interposer through electrode 120 may contact the lower surface of the interposer pad 130. The interposer through electrode 120 may provide an electrical connection path between a semiconductor device to be positioned on the first surface 110_p of the interposer substrate 110 and a semiconductor device to be mounted on the second surface 110_q of the interposer substrate 110. For example, the interposer through electrode 120 may include a pillar-shaped conductive plug penetrating at least a portion of the interposer substrate 110 and a cylindrical conductive barrier film surrounding a sidewall of the conductive plug. The conductive barrier film may include at least one material selected from Ti, TiN, Ta, TaN, Ru, Co, Mn, WN, Ni and NiB. The conductive plug may include at least one material selected from Cu alloys such as Cu, CuSn, CuMg, CuNi, CuZn, CuPd, CuAu, CuRe and CuW, W, W alloy, Ni, Ru, and Co.

According to an example embodiment, the first semiconductor chip 200 may be placed on the first surface 110_p of the interposer 100. The first semiconductor chip 200 may include a first semiconductor substrate 201, a first through electrode 202, a first bonding pad 211, a first bonding insulation layer 212, a first front side pad 221, and a first front side insulation layer 222.

According to an example embodiment, the first semiconductor substrate 201 may provide a back side 201_b facing a passive device 320 while being opposite to a front side 201_f facing the interposer 100. According to an example embodiment, the active layer including devices such as transistors and resistors and capacitors may be placed near the front side 201_f of the first semiconductor substrate 201. However, the first semiconductor substrate 201 is not necessarily limited to the above. According to an example embodiment, the active layer may be placed near the back side 201_b of the first semiconductor substrate 201. The first semiconductor substrate 201 may include a semiconductor such as silicon and germanium, and the first semiconductor substrate 201 may be, for example, a silicon substrate.

According to an example embodiment, the width of the first semiconductor chip 200 in the second direction D2 and/or the third direction D3 may be smaller than the width of the interposer 100 in the second direction D2 and/or the third direction D3, and the first semiconductor chip 200 may completely overlap with the interposer 100 along the first direction D1.

According to an example embodiment, the first semiconductor chip 200 may be a logic chip configured to perform data processing, calculation, and control functions. For example, the first semiconductor chip 200 may be a semiconductor chip including a high performance circuit. The first semiconductor chip 200 may include a system on chip (SOC). According to an example embodiment, the first semiconductor chip 200 may include at least one of a central processing unit (CPU), a graphics processing unit (GPU), memory, a controller, a codec, a sensor, and a communication unit.

According to an example embodiment, the first through electrode 202 may penetrate at least a portion of the first semiconductor substrate 201 in the first direction D1. The first through electrode 202 may extend from the front side 201_f to the back side 201_b of the first semiconductor substrate 201 according to an example embodiment. A plurality of first through electrodes 202 may be provided, and the plurality of first through electrodes 202 may be arranged along the second direction D2 and/or the third direction D3. The composition of the first through electrode 202 and the material included in the first through electrode 202 may be substantially the same as the interposer through electrode 120, and thus detailed explanations are omitted.

According to an example embodiment, the plurality of first bonding pads 211 and the first bonding insulation layer 212 may be arranged on the back side 201_b of the first semiconductor substrate 201. Each of the plurality of first bonding pads 211 may be positioned corresponding to the plurality of first through electrodes 202. The upper surface of a plurality of first bonding pads 211 may be connected to a lower surface of the plurality of first through electrodes 202. The first bonding insulation layer 212 may surround a plurality of first bonding pads 211 on the back side 201_b of the first semiconductor substrate 201. According to an example embodiment, the outermost side surface of the first bonding insulation layer 212 may be aligned with the side surface of the first semiconductor substrate 201. However, as will be described later, depending on the example embodiment, in the annealing process for the first bonding insulation layer 212, some operations dielectric-dielectric bonding may occur between the first molding layers 420, so that an interface may not be formed between the first bonding insulation layer 212 and the first molding layer 420.

According to an example embodiment, the plurality of first front side pads 221 may be arranged on the front side 201_f of the first semiconductor substrate 201. Each of the plurality of first front side pads 221 may be positioned corresponding to the plurality of first through electrodes 202. Lower surfaces of the plurality of first front side pads 221 may be connected to upper surfaces of the plurality of first through electrodes 202. The first front side insulation layer 222 may surround the plurality of first front side pads 221 on the front side 201_f of the first semiconductor substrate 201. Here, the outermost side surface of the first front side insulation layer 222 may be aligned with the side surface of the first semiconductor substrate 201, and may be in contact with the first molding layer 420.

According to an example embodiment, the bonding film 430 and the conductive pattern 440 may be placed on the front side 201_f of the first semiconductor substrate 201. The bonding film 430 may be interposed between the first semiconductor chip 200 and the interposer 100 and configured to adhere to the first semiconductor chip 200 and the interposer 100. The conductive pattern 440 may be provided within the bonding film 430 and configured to electrically connect a plurality of conductive posts 410 and the interposer through electrode 120, or to electrically connect between the first front side pad 221 and the interposer through electrode 120. FIG. 2 illustrates that the conductive pattern 440 is a pattern embedded in the bonding film 430. However, according to an example embodiment, the conductive pattern 440 may be a conductive pad surrounded by the bonding film 430. When the conductive pattern 440 is a conductive pad, the lower surface of the conductive pattern 440 may be exposed to the lower surface of the bonding film 430, and the upper surface of the conductive pattern 440 may be exposed to the upper surface of the bonding film 430. For example, the bonding film 430 may include silicon oxide, silicon nitride, silicon oxynitride, or silicon oxide. For example, the conductive pattern 440 may include at least one metal selected from tungsten (W), aluminum (Al) and copper (Cu).

According to an example embodiment, the second semiconductor chip 300 may be placed on the back side 201_b of the first semiconductor substrate 201. The second semiconductor chip 300 may include a second semiconductor substrate 301, a second front side pad 302, a second front side insulation layer 311, a second through electrode 312, a second bonding pad 331, the passive device 320 and the second bonding insulation layer 332.

According to an example embodiment, the second semiconductor substrate 301 may provide a front side 301_f facing a redistribution structure 500 while being opposite to a back side 301_b facing the first semiconductor chip 200. The width of the second semiconductor substrate 301 in the second direction D2 and the width of the interposer substrate 110 in the second direction D2 may be equal to the first width W1. In addition, as illustrated in FIG. 1, the width of the second semiconductor substrate 301 in the third direction D3 and the width of the interposer substrate 110 in the third direction D3 may be the same. In other words, from a horizontal perspective (from the perspective of intersecting the first direction D1), the width of the interposer substrate 110 and the width of the second semiconductor substrate 301 may be substantially identical. According to an example embodiment, an area of the second surface 110_q of the interposer 100 may be substantially identical to an area of front side 201_f of the second semiconductor substrate 301. The second semiconductor substrate 301 may include a semiconductor such as silicon and germanium, and the second semiconductor substrate 301 may be, for example, a silicon substrate. As used herein, the expression “substantially equal” may refer to having the same value relative to other value(s) compared therewith, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

According to an example embodiment, the second semiconductor chip 300 may be a passive device chip including the passive device 320. The passive device 320 may be provided within the second semiconductor substrate 301. The passive device 320 may include, for example, an integrated stack capacitor (ISC). In an example embodiment, the passive devices 320 that enables the capacitance density required by the first semiconductor chip 200 may be placed in most of the entire second semiconductor substrate 301 of the second semiconductor chip 300. The passive device 320 may suppress power noise in high frequency bands of several hundred MHz, and have a much higher capacitance density than multilayer ceramic capacitors (MLCCs) or land side capacitors (LSCs).

According to an example embodiment, the second front side pad 302 may be positioned so that a lower surface is exposed to the front side 301_f of the second semiconductor substrate 301. A plurality of second front side pads 302 may be provided, and the plurality of second front side pads 302 may be arranged in the second direction D2 and/or the third direction D3 with lower surfaces being exposed on the front side 301_f of the second semiconductor substrate 301. The plurality of second front side pads 302 may provide terminals through which the second through electrode 312 disposed on the front side 301_f of the second semiconductor substrate 301 may be electrically connected to semiconductor elements within the second semiconductor substrate 301. For example, the plurality of second front side pads 302 may include at least one metal selected from tungsten (W), aluminum (Al) and copper (Cu).

According to an example embodiment, the second front side insulation layer 311 and the second through electrode 312 may be arranged on the front side 301_f of the second semiconductor substrate 301. A plurality of second through electrodes 312 may be provided, and each of the plurality of second through electrodes 312 may be connected to the second front side pad 302. The second front side insulation layer 311 may surround the plurality of second through electrodes 312 on the front side 301_f of the second semiconductor substrate 301. The lower surface of the second front side insulation layer 311 may be positioned to be coplanar with the lower surface of the plurality of second through electrodes 312. Further, the outermost side surface of the second front side insulation layer 311 may be formed to be aligned with the side surface of the second semiconductor substrate 301. The plurality of second through electrodes 312 may provide electrical connection paths for other semiconductor devices or wiring to be physically connected to the second semiconductor chip 300. The redistribution structure 500 disposed on the front side 301_f of the second semiconductor substrate 301 may be electrically connected to the second semiconductor chip 300 through the plurality of second through electrodes 312.

According to an example embodiment, the plurality of second bonding pads 331 and the second bonding insulation layer 332 may be arranged on the back side 301_b of the second semiconductor substrate 301. Each of the plurality of second bonding pads 331 may be arranged to correspond to a plurality of first bonding pads 211 and the conductive posts 410 of the first semiconductor chip 200. Even though not illustrated in detail in the drawing, inside the second semiconductor substrate 301, wiring electrically connected to the passive device 320 may be provided, and the wiring may electrically be connected to the plurality of second bonding pads 331.

According to an example embodiment, the second bonding insulation layer 332 may surround the plurality of second bonding pads 331 on the back side 301_b of the second semiconductor substrate 301. According to an example embodiment, the outermost side surface of the second bonding insulation layer 332 may be aligned with the side surface of the second semiconductor substrate 301.

According to an example embodiment, a part of the first bonding pad 211 of the first semiconductor chip 200 and a part of the second bonding pad 331 of the second semiconductor chip 300 may be directly bonded to each other by a metal-metal bonding method. Between the first semiconductor chip 200 and the second semiconductor chip 300, the first bonding pad 211 and the second bonding pad 331 may be bonded to each other by Cu-Cu hybrid bonding. The first bonding pad 211 and the second bonding pad 331 may include at least one metal selected from tungsten (W), aluminum (Al) and copper (Cu).

According to an example embodiment, the first bonding insulation layer 212 of the first semiconductor chip 200 and a center bonding area 332_C of the second bonding insulation layer 332 of the second semiconductor chip 300 may be directly bonded to each other by the dielectric-dielectric bonding method. The first bonding insulation layer 212 and the second bonding insulation layer 332 may form a bonding structure by including the same insulating material. The center bonding area 332_C of the second bonding insulation layer 332 and the first bonding insulation layer 212 may be bonded to each other by a high-temperature annealing process while in contact with each other. Here, the bonding structure may have a stronger bonding strength due to covalent bonding.

According to an example embodiment, the conductive post 410 may extend in the first direction D1 between the second semiconductor chip 300 and the bonding film 430 to provide an electrical connection path between the second semiconductor chip 300 and the conductive pattern 440 in the bonding film 430. The plurality of conductive posts 410 may be provided, and the plurality of conductive posts 410 may be arranged to surround the first semiconductor chip 200. For example, the conductive post 410 may include a pillar-shaped conductive plug penetrating at least a portion of the first molding layer 420 and a cylindrical conductive barrier film surrounding a side wall of the conductive plug. The conductive barrier film may include at least one material selected from Ti, TiN, Ta, TaN, Ru, Co, Mn, WN, Ni, and NiB. The conductive plug may include at least one material selected from Cu alloys such as Cu, CuSn, CuMg, CuNi, CuZn, CuPd, CuAu, CuRe and CuW, W, W alloy, Ni, Ru, and Co.

According to an example embodiment, the first molding layer 420 may be configured to seal the plurality of conductive posts 410 and the first semiconductor chip 200 between the bonding film 430 and the second semiconductor chip 300. The first molding layer 420 may cover the side surface of the first semiconductor chip 200 and the side surface of the plurality of conductive posts 410. The first molding layer 420 may contain the same material as the first bonding insulation layer 212 and the second bonding insulation layer 332. As will be described later, the first molding layer 420 may include the same material as the second bonding insulation layer 332 so as to be directly bonded to the second bonding insulation layer 332 via dielectric-dielectric bonding.

According to an example embodiment, the first molding layer 420 and the second bonding insulation layer 332 may form a bonding structure using a dielectric-dielectric bonding method. An outer bonding area 332_O of the first molding layer 420 and the second bonding insulation layer 332 may be directly bonded to each other by a dielectric-dielectric bonding method. The outer bonding area 332_O of the second bonding insulation layer 332 and the first molding layer 420 may be bonded to each other by a high-temperature annealing process while in contact with each other. Here, the bonding structure may have a stronger bonding strength due to the covalent bonding.

As illustrated in FIG. 3 and FIG. 4, the second bonding insulation layer 332 may include the center bonding area 332_C that is directly bonded to the first bonding insulation layer 212 and the outer bonding area 332_O that is directly bonded to the first molding layer 420. Further, the second bonding pad 331 may include a center bonding pad 331_C surrounded by the center bonding area 332_C of the second bonding insulation layer 332 and an outer bonding pad 331_O surrounded by the outer bonding area 332_O of the second bonding insulation layer 332. As described above, the center bonding pad 331_C may be defined as a pad that is directly bonded to the first bonding pad 211 by the metal-metal bonding method.

According to an example embodiment, the conductive post 410 and the outer bonding pad 331_O of the second semiconductor chip 300 may be directly bonded to each other by the metal-metal bonding method. Between the conductive post 410 and the second semiconductor chip 300, the conductive post 410 and the outer bonding pad 331_O may be bonded to each other by the Cu—Cu hybrid bonding.

According to an example embodiment, the first bonding insulation layer 212, the second bonding insulation layer 332, the first front side insulation layer 222, and the second front side insulation layer 311 may include silicon oxide, silicon nitride, silicon oxynitride, an insulating material having a lower dielectric constant than silicon oxide, or a combination thereof. In some example embodiments, the first bonding insulation layer 212, the second bonding insulation layer 332, the first front side insulation layer 222 and the second front side insulation layer 311 may include a tetraethyl orthosilicate (TEOS) film or an ultra-low K (ULK) film having an ultra-low dielectric constant K of about 2.2 to 2.4. The ULK film may include a SiOC film or a SiCOH film.

According to an example embodiment, in the process of bonding the second semiconductor chip 300 on a structure composed of the first semiconductor chip 200, the conductive post 410 surrounding the first semiconductor chip 200 and the first molding layer 420 using a wafer-to-wafer bonding method, the plurality of second bonding pads 331 may be distinguished as the outer bonding pad 331_O that is directly bonded to the conductive post 410 and the center bonding pad 331_C that is directly bonded to the first bonding pad 211. When the first semiconductor chip 200 and the second semiconductor chip 300 are bonded using a hybrid bonding method, the electrical connection distance between the logic device in the first semiconductor chip 200 and the passive device 320 in the second semiconductor chip 300 may be shortened. As the electrical connection distance between the logic element and the passive device 320 is shortened, the parasitic resistance or parasitic inductance between the first semiconductor chip 200 and the second semiconductor chip 300 may be eliminated. Thus, the signal transmission speed and power efficiency between the first semiconductor chip 200 and the second semiconductor chip 300 may be improved. As illustrated in FIG. 3, through the structure of the semiconductor package 10, an electrical signal path connecting the memory chip structure (the first memory chip structure 600a and the second memory chip structure 600b)—the interposer 100—the first semiconductor chip 200—the second semiconductor chip 300 may be implemented. The electrical connection distance may refer to the physical distance between components or the electrical length.

According to an example embodiment, as the electrical connection distance between the first semiconductor chip 200 including the high performance circuit and the second semiconductor chip 300 including the passive device 320 is shortened, the speed at which signals and power are transmitted and responded between the first semiconductor chip 200 and the second semiconductor chip 300 may be increased. Accordingly, the PI of the semiconductor package 10 may be improved.

According to an example embodiment, the semiconductor package 10 may further include the redistribution structure 500, the first memory chip structure 600a, the second memory chip structure 600b, and a second molding layer 900.

According to an example embodiment, the redistribution structure 500 may be placed on the lower surface of the second front side insulation layer 311. The redistribution structure 500 may include a redistribution insulation layer 510, a first redistribution pad 520, a second redistribution pad 530, a redistribution pattern 540, and a redistribution via 550.

According to an example embodiment, the redistribution insulation layer 510 may be disposed on the lower surface of the second front side insulation layer 311. FIG. 2 illustrates that the redistribution insulation layer 510 is an insulation layer of a single layer, but according to an example embodiment, the redistribution insulation layer 510 may have a structure in which a plurality of insulation layers are laminated at different levels along the first direction D1. The upper surface of the first redistribution pad 520 may be positioned so as to be exposed to the upper surface of the redistribution insulation layer 510. According to an example embodiment, when the redistribution insulation layer 510 has a structure in which a plurality of insulation layers are laminated at different levels along the first direction D1, the upper surface of the first redistribution pad 520 may be positioned so that the upper surface of the uppermost redistribution insulation layer 510 is exposed. The first redistribution pad 520 may be physically connected to the second through electrode 312.

According to an example embodiment, the lower surface of the second redistribution pad 530 may be positioned so as to be exposed to the lower surface of the redistribution insulation layer 510. According to an example embodiment, when the redistribution insulation layer 510 has a structure in which a plurality of insulation layers are laminated at different levels along the first direction D1, the lower surface of the second redistribution pad 530 may be positioned so that the lower surface of the lowermost redistribution insulation layer 510 is exposed. The second redistribution pad 530 may be physically connected to an external connecting terminal 560.

According to an example embodiment, the redistribution pattern 540 may extend laterally within the redistribution insulation layer 510. The redistribution pattern 540 may provide lateral electrical wiring within the redistribution insulation layer 510. FIG. 2 illustrates that the plurality of redistribution patterns 540 are spaced apart in the second direction D2 and/or the third direction D3 while having the same level in the first direction D1. However, according to an example embodiment, the plurality of redistribution patterns 540 may be provided as multi-layered patterns with different levels in the first direction D1.

According to an example embodiment, the redistribution via 550 may be placed between the first redistribution pad 520 and the redistribution pattern 540 or between the second redistribution pad 530 and the redistribution pattern 540. The redistribution via 550 is in contact with the lower surface of the first redistribution pad 520 and the upper surface of the redistribution pattern 540, thereby physically connecting the first redistribution pad 520 and the redistribution pattern 540. Alternatively, the redistribution via 550 is in contact with the upper surface of the second redistribution pad 530 and the lower surface of the redistribution pattern 540, thereby physically connecting the second redistribution pad 530 and the redistribution pattern 540. According to an example embodiment, when the plurality of redistribution patterns 540 are provided as multi-layered patterns with different levels in the first direction D1, the redistribution via 550 may physically connect between the redistribution patterns 540 in a multi-layer structure. In an example embodiment, the redistribution via 550 may have a tapered shape, with the width becoming narrower as the redistribution via 550 gets closer to the first redistribution pad 520 from the second redistribution pad 530.

According to an example embodiment, the redistribution insulation layer 510 may include silicon oxide, silicon nitride, silicon oxynitride, an insulating material having a lower dielectric constant than silicon oxide, or a combination thereof. Further, the first redistribution pad 520, the second redistribution pad 530, the redistribution pattern 540 and the redistribution via 550 may include at least one metal selected from tungsten (W), aluminum (Al) and copper (Cu).

According to an example embodiment, the first memory chip structure 600a and the second memory chip structure 600b may be mounted on the second surface 110_q of the interposer substrate 110. The first memory chip structure 600a may include a first buffer chip 610a, a first connecting pad 620a, a first connecting terminal 630a and a plurality of first memory chips 640a. The second memory chip structure 600b may include a second buffer chip 610b, a second connecting pad 620b, a second connecting terminal 630b and a plurality of second memory chips 640b.

According to an example embodiment, the first buffer chip 610a includes a serial-parallel conversion circuit and may be a buffer chip for controlling the plurality of first memory chips 640a, and the plurality of first memory chips 640a may be a chip including memory cells. For example, the first memory chip structure 600a including the first buffer chip 610a and the plurality of first memory chips 640a may be high bandwidth memory (HBM). The first buffer chip 610a may be called the HBM controller die, and each of the plurality of first memory chips 640a may be called the DRAM die.

According to an example embodiment, the first connecting pad 620a may be placed under the lower surface of the first buffer chip 610a. According to an example embodiment, the redistribution structure may be further provided under the first buffer chip 610a, and the first connecting pad 620a may be placed under the lower surface of the redistribution structure. The first connecting terminal 630a may be attached to the first connecting pad 620a. For example, the first connecting terminal 630a may be a solder ball or a bump. The first connecting terminal 630a is interposed between the first connecting pad 620a and the interposer pad 130, and may electrically connect the first connecting pad 620a and the interposer pad 130.

According to an example embodiment, the first buffer chip 610a and the plurality of first memory chips 640a may be stacked along the first direction D1 in a hybrid bonding manner. However, the method by which the first buffer chip 610a and the plurality of first memory chips 640a are bonded is not necessarily limited to the hybrid bonding method. According to an example embodiment, the first buffer chip 610a and the plurality of first memory chips 640a may be bonded to each other in a flip-chip manner using bumps or solder balls.

According to an example embodiment, the second memory chip structure 600b may be arranged spaced apart from the first memory chip structure 600a in the second direction D2. The description of the second memory chip structure 600b largely overlaps with the description of the first memory chip structure 600a, and thus specific explanations will be omitted below.

According to an example embodiment, the second molding layer 900 may be configured to seal the first memory chip structure 600a and the second memory chip structure 600b on the second surface 110_q of the interposer substrate 110. The second molding layer 900 may be configured to firmly secure the first memory chip structure 600a and the second memory chip structure 600b on the interposer substrate 110. In an example embodiment, the second molding layer 900 may include an underfill material including at least one of an insulating polymer and an epoxy resin. For example, the second molding layer 900 may include epoxy molding compound (EMC). The material of the second molding layer 900 may be different from the material of the first molding layer 420. The outermost side surface of the second molding layer 900 may be aligned with the side surface of the semiconductor package 10.

According to an example embodiment, it is illustrated that the semiconductor package has two memory chip structures (the first memory chip structure 600a and the second memory chip structure 600b) mounted on the interposer 100. However, according to an example embodiment, three memory chip structures or more may be mounted on the interposer 100. Further, according to an example embodiment, one memory chip structure may be mounted on the interposer 100.

According to an example embodiment, the first semiconductor chip 200, the first molding layer 420, the interposer 100, the bonding film 430 and the second molding layer 900 may have their side surfaces aligned with each other. Specifically, the side surface of the first semiconductor substrate 201, the outermost side surface of the first molding layer 420, the side surface of the interposer substrate 110, the side surface of the bonding film 430, and the outermost side surface of the second molding layer 900 may be aligned. In addition thereto, the side surface of the redistribution structure 500 may also be aligned with the side surface of the first semiconductor substrate 201. Further, the outermost side surface of the second bonding insulation layer 332 and the side surface of the first semiconductor substrate 201 may also be aligned.

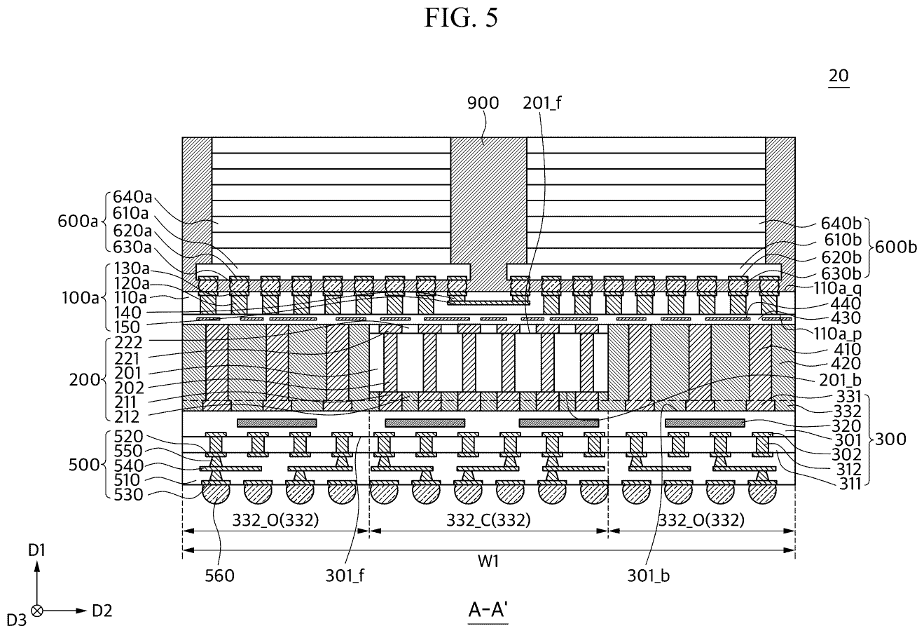

FIG. 5 is a cross-sectional view illustrating a semiconductor package 20 according to another example embodiment. The cross-sectional view of the semiconductor package 20 illustrated in FIG. 5 corresponds to the cross-sectional view of the semiconductor package 10 along the A-A′ cross-section illustrated in FIG. 2.

The semiconductor package 20 illustrated in FIG. 5 is almost identical or similar to the semiconductor package 10 illustrated in FIG. 1 to FIG. 4 except that an interposer 100a further includes an interposer via 140 and an interposer pattern 150. Below, the differences from the semiconductor package 10 illustrated in FIG. 1 to FIG. 4 are mainly explained.

According to an example embodiment, the interposer 100a may include the interposer pattern 150 extending in the second direction D2 and/or the third direction D3 to provide electrical wiring within an interposer substrate 110a in the second direction D2 and/or the third direction D3, and the interposer via 140 connecting an interposer pad 130a and the interposer pattern 150. The interposer via 140 may provide electrical wiring between the interposer pad 130a and the interposer pattern 150 within the interposer substrate 110a.

According to an example embodiment, the interposer pad 130a may be connected with the connecting terminal (the first connecting terminal 630a and the second connecting terminal 630b) of each of one pair of memory chip structures (the first memory chip structure 600a and the second memory chip structure 600b) mounted on a second surface 110a_q opposite to a first surface 110a_p of the interposer substrate 110a. Some of the plurality of interposer pads 130a may be in contact with the interposer via 140 and electrically connected to the interposer pattern 150 through the interposer via 140. When data communication between a pair of memory chip structures (the first memory chip structure 600a and the second memory chip structure 600b) is required, the electrical connection distance between one pair of memory chip structures (the first memory chip structure 600a and the second memory chip structure 600b) may be shortened through the interposer pattern 150 in the interposer substrate 110a. For example, the interposer pattern 150 may be a conductive pattern or may be an embedded multi-die interconnected bridge (EMIB).

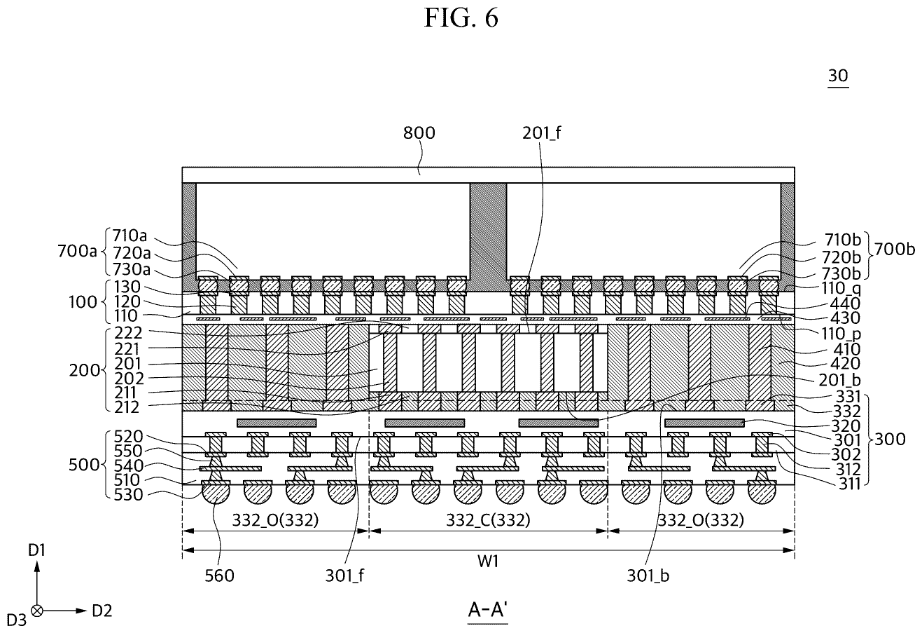

FIG. 6 is a cross-sectional view illustrating a semiconductor package 30 according to another example embodiment. The cross-sectional view of the semiconductor package 30 illustrated in FIG. 6 corresponds to the cross-sectional view of the semiconductor package 10 along the A-A′ cross-section illustrated in FIG. 2.

The semiconductor package 30 illustrated in FIG. 6 is almost identical or similar to the semiconductor package 10 illustrated in FIG. 1 to FIG. 4 except that a third semiconductor chip 700a and a fourth semiconductor chip 700b are mounted on the interposer substrate 110a, and a heat radiation member is placed on the third semiconductor chip 700a and the fourth semiconductor chip 700b. Differences from the semiconductor package 10 illustrated in FIG. 1 to FIG. 4 are specifically explained.

According to an example embodiment, the semiconductor package 30 may include the third semiconductor chip 700a and the fourth semiconductor chip 700b mounted on the second surface 110a_q of the interposer substrate 110a. Here, the third semiconductor chip 700a and the fourth semiconductor chip 700b may be semiconductor chips that do not have a stacked memory chip structure. For example, the third semiconductor chip 700a and the fourth semiconductor chip 700b may be IC chips in which a plurality of integrated circuits are formed. The plurality of integrated circuits may be provided in a first body 710a of the third semiconductor chip 700a and a second body 710b of the fourth semiconductor chip 700b. The plurality of integrated circuits may include, for example, a metal-oxide-semiconductor field effect transistor (MOSFET) such as a complementary metal-oxide semiconductor (CMOS) transistor, a system large scale integration (LSI), a flash memory, a DRAM, a SRAM, an EEPROM, a PRAM, a MRAM, and a RERAM, an image sensor such as CMOS imaging sensor (CIS) and a micro-electro-mechanical system (MEMS), an active device, a passive device and the like.

According to an example embodiment, the third semiconductor chip 700a may include, in addition to the first body 710a, a third connecting pad 720a and a third connecting terminal 730a. The fourth semiconductor chip 700b may include, in addition to the second body 710b, a fourth connecting pad 720b and a fourth connecting terminal 730b. The third connecting pad 720a and the fourth connecting pad 720b are substantially identical to the first connecting pad 620a and the second connecting pad 620b described with reference to FIG. 1 to FIG. 4, except that the third connecting pad 720a and the fourth connecting pad 720b are provided in the first body 710a and the second body 710b. The third connecting terminal 730a and the fourth connecting terminal 730b are substantially identical to the first connecting terminal 630a and the second connecting terminal 630b described with reference to FIG. 1 to FIG. 4, except that the third connecting terminal 730a and the fourth connecting terminal 730b are connected to the first body 710a and the second body 710b. Therefore, the contents already explained with reference to FIG. 1 to FIG. 4 are omitted below.

According to an example embodiment, a heat radiation member 800 may be placed on the third semiconductor chip 700a and the fourth semiconductor chip 700b. The heat radiation member 800 may extend along the upper surfaces of the first body 710a and the second body 710b. The side surface of the heat radiation member 800 may be aligned with the side surface of the second molding layer 900. The heat radiation member 800 may include a material having high thermal conductivity, such as a metal and metal nitride. The heat radiation member 800 has high thermal conductivity and may be configured to radiate high temperature heat generated from the third semiconductor chip (700a) and the fourth semiconductor chip (700b) to the outside. In some example embodiments, the heat radiation member 800 may include aluminum, titanium, titanium nitride, nickel, nickel vanadium, silver, gold, copper, or combinations thereof.

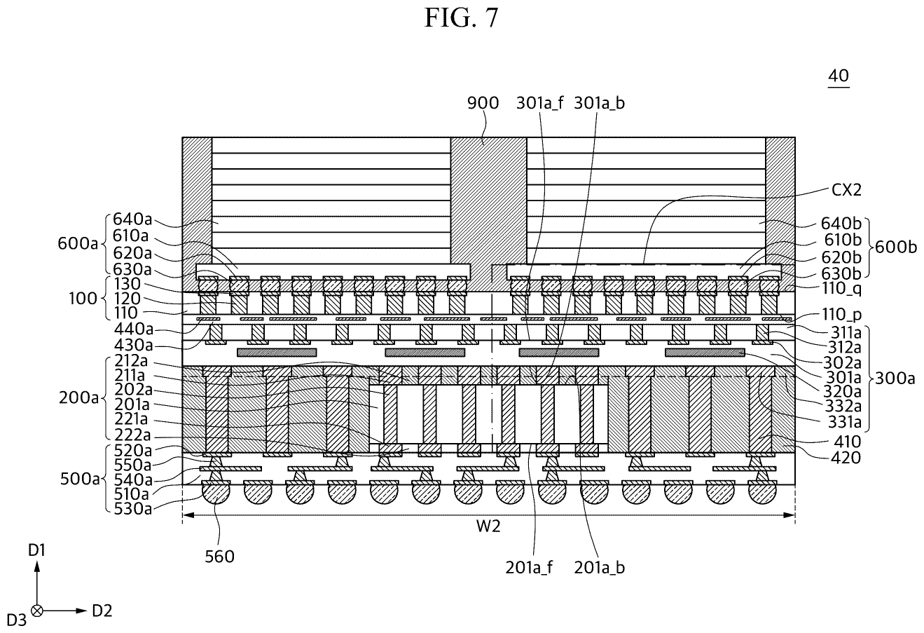

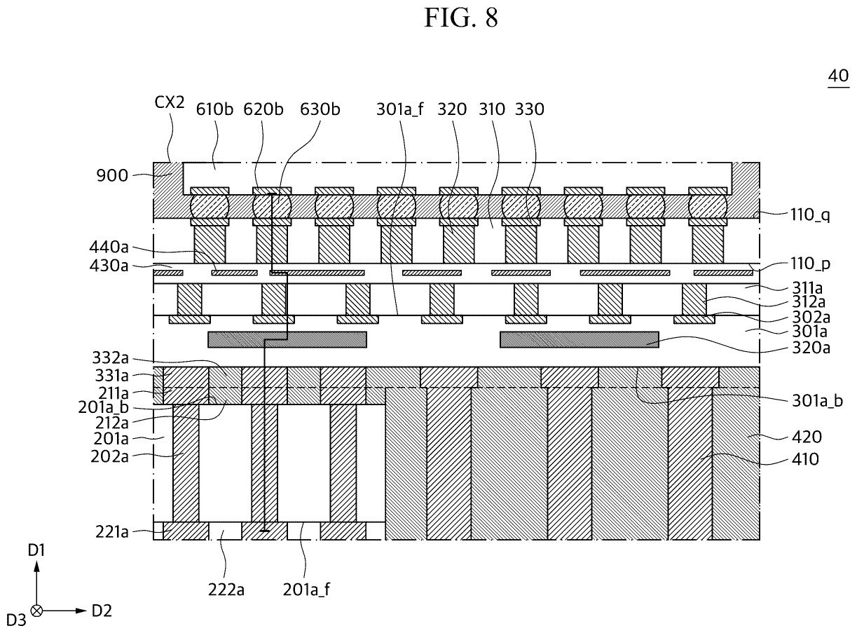

FIG. 7 is a cross-sectional view illustrating a semiconductor package 40 according to another example embodiment. FIG. 8 is an enlarged view of the portion indicated as “CX2” in FIG. 7. The cross-sectional view of the semiconductor package 40 illustrated in FIG. 7 corresponds to the cross-sectional view of the semiconductor package 10 along the A-A′ cross-section illustrated in FIG. 2.

The semiconductor package 40 illustrated in FIG. 7 and FIG. 8 is substantially identical or similar to the semiconductor package 10 illustrated in FIG. 1 to FIG. 4, except that a second semiconductor chip 300a is placed between the interposer 100 and a first semiconductor chip 200a. Hereinafter, differences from the semiconductor package 10 illustrated in FIG. 1 to FIG. 4 are specifically explained.

According to an example embodiment, the first semiconductor chip 200a may include a first semiconductor substrate 201a, a first through electrode 202a, a first bonding pad 211a, a first bonding insulation layer 212a, a first front side pad 221a, and a first front side insulation layer 222a. The first through electrode 202a is substantially identical to the first through electrode 202 illustrated in FIG. 2, and thus detailed explanations thereof are omitted.

According to an example embodiment, the first semiconductor substrate 201a may provide a front side 201a_f facing the second semiconductor chip 300a while being opposite to a back side 201a_b facing the interposer 100. According to an example embodiment, an active layer may be placed near the front side 201a_f of the first semiconductor substrate 201a. However, the present disclosure is not limited thereto, and in another example embodiment, the active layer may be placed near the back side 201a_b of the first semiconductor substrate 201a.

According to an example embodiment, the plurality of first bonding pads 211a and the first bonding insulation layer 212a may be arranged on the back side 201a_b of the first semiconductor substrate 201a. Each of the plurality of first bonding pads 211a may be placed corresponding to a plurality of first through electrodes 202a. The first bonding insulation layer 212a may surround the plurality of first bonding pads 211a on the back side 201a_b of the first semiconductor substrate 201a.

According to an example embodiment, the second semiconductor chip 300a may be placed on the back side 201a_b of the first semiconductor substrate 201a. The second semiconductor chip 300a may include a second semiconductor substrate 301a, a second front side pad 302a, a second front side insulation layer 311a, a second through electrode 312a, a second bonding pad 331a, a passive device 320a, and a second bonding insulation layer 332a. The second front side pad 302a and the passive device 320a are substantially identical to the second front side pad 302 and the passive device 320 described with reference to FIG. 1 to FIG. 4, and thus detailed descriptions are omitted.

According to an example embodiment, the second semiconductor substrate 301a may provide a front side 301a_f facing the interposer 100 while being opposite to a back side 301a_b facing the first semiconductor chip 200a. The width of the second semiconductor substrate 301a in the second direction D2 and the width of the interposer substrate 110 in the second direction D2 may be equal to the second width W2. Addition thereto, as illustrated in FIG. 7, the width of the second semiconductor substrate 301a in the third direction D3 and the width of the interposer substrate 110 in the third direction D3 may also be the same. In other words, from a horizontal perspective (from the perspective intersecting the first direction D1), the width of the interposer substrate 110 and the width of the second semiconductor substrate 301a may be substantially the same.

According to an example embodiment, the second front side insulation layer 311a and the second through electrode 312a may be arranged on the front side 301_f of the second semiconductor substrate 301a. Unlike the second front side insulation layer 311 shown in FIG. 1 to FIG. 4, the second front side insulation layer 311a illustrated in FIG. 7 may be interposed between a bonding film 430a and the second semiconductor substrate 301a. Unlike the second through electrode 312 shown in FIG. 1 to FIG. 4, the second through electrode 312a may provide an electrical connection path between a conductive pattern 440a in the bonding film 430a and the second front side pad (302a).

According to an example embodiment, a redistribution structure 500a may be placed on the lower surface of the first molding layer 420. The redistribution structure 500a may include a redistribution insulation layer 510a, a first redistribution pad 520a, a second redistribution pad 530a, a redistribution pattern 540a, and a redistribution via 550a. The redistribution structure 500a illustrated in FIG. 7 may be substantially identical to the redistribution structure 500 illustrated in FIG. 2, except that the redistribution structure 500a illustrated in FIG. 7 is placed on the front side 201a_f of the first semiconductor substrate 201a. Therefore, detailed description on the redistribution structure 500a is omitted below.

According to an example embodiment, the plurality of second bonding pads 331a and the second bonding insulation layer 332a may be arranged on the back side 301a_b of the second semiconductor substrate 301a. Each of the plurality of second bonding pads 331a may be arranged corresponding to the plurality of first bonding pads 211a and the conductive post 410 of the first semiconductor chip 200a. Even though not illustrated in detail in the drawing, in the second semiconductor substrate 301a, wiring electrically connected to the passive device 320a may be provided, and the wiring may be electrically connected to the plurality of second bonding pads 331a.

According to an example embodiment, a portion of the first bonding pad 211a of the first semiconductor chip 200a and a portion of the second bonding pad 331a (for example, a pad corresponding to the center bonding pad 331_C of FIG. 3) arranged at the center of the second semiconductor chip 300a may be directly bonded to each other by the metal-metal bonding method. Between the first semiconductor chip 200a and the second semiconductor chip 300a, the first bonding pad 211a and the second bonding pad 331a may be bonded to each other by the Cu—Cu hybrid bonding method. The direction bonding between the first bonding pad 211a and the second bonding pad 331a located on the periphery of the second semiconductor chip 300a illustrated in FIG. 7 may be substantially the same as the direct bonding between the first bonding pad 211 and the outer bonding pad 331_O described with reference to FIG. 1 to FIG. 4.

According to an example embodiment, the first bonding insulation layer 212a of the first semiconductor chip 200a and the second bonding insulation layer 332a (for example, corresponding to the outer bonding area 332_O of FIG. 3) located at the center of the second semiconductor chip 300a may be directly bonded to each other by dielectric-dielectric bonding. The direct bonding between the first bonding insulation layer 212a and the second bonding insulation layer 332a as shown in FIG. 7 may be substantially identical to the direct bonding between the first bonding insulation layer 212 and the outer bonding area 332_O of the second bonding insulation layer 332 as described with reference to FIG. 1 to FIG. 4.

According to an example embodiment, the first molding layer 420 may be configured to seal the plurality of conductive posts 410 and the first semiconductor chip 200a between the redistribution structure 500 and the second semiconductor chip 300a. The first molding layer 420 may contain the same material as the first bonding insulation layer 212a and the second bonding insulation layer 332a.

According to an example embodiment, the first molding layer 420 and the second bonding insulation layer 332a may form a bonding structure using a dielectric-dielectric bonding method. Like the second bonding insulation layer 332a illustrated in FIG. 1 to FIG. 4, the outer area of the second bonding insulation layer 332a may form a bonding structure with the first molding layer 420 using dielectric-dielectric bonding, and the center area of the second bonding insulation layer 332a may form a bonding structure with the first bonding insulation layer 212a by dielectric-dielectric bonding.

According to an example embodiment, the conductive post 410 and some of the plurality of second bonding pads 331a may be directly bonded to each other by metal-metal bonding. Like the plurality of second bonding pads 331 illustrated in FIG. 1 to FIG. 4, the second bonding pad 331a, located on the outer side, may be bonded to the conductive post 410 using the metal-metal bonding method, and the second bonding pad 331a positioned on the center side may be bonded to the first bonding pad 211a using the metal-metal bonding method.

According to an example embodiment, when the first semiconductor chip 200a and the second semiconductor chip 300a are bonded using a hybrid bonding method, the electrical connection distance between the logic device in the first semiconductor chip 200a and the passive device 320a in the second semiconductor chip 300a may be shortened. As illustrated in FIG. 8, through the structure of the semiconductor package 40, an electrical signal path connecting the memory chip structure (the first memory chip structure 600a and the second memory chip structure 600b)—the interposer 100—the second semiconductor chip 300a—the first semiconductor chip 200a may be implemented.

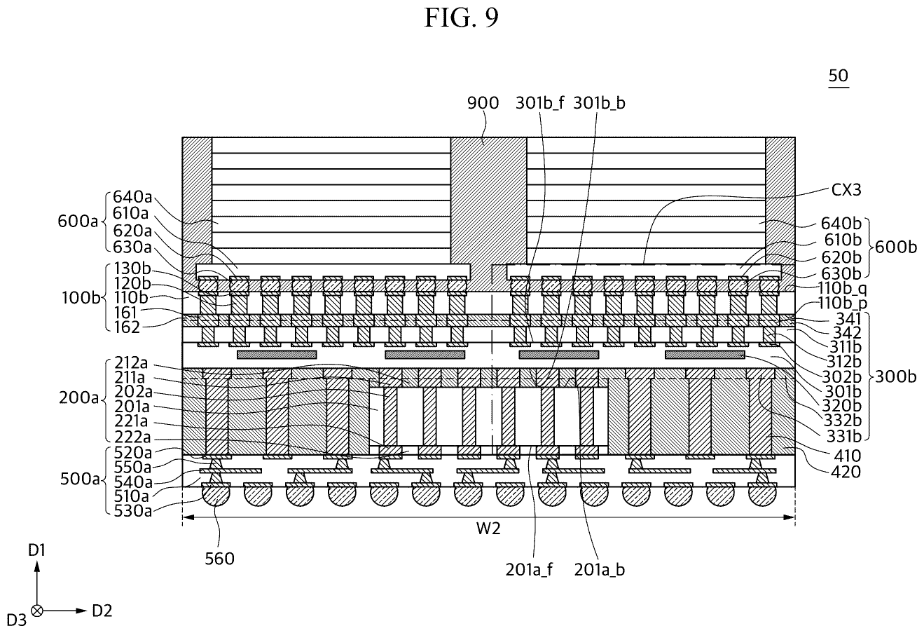

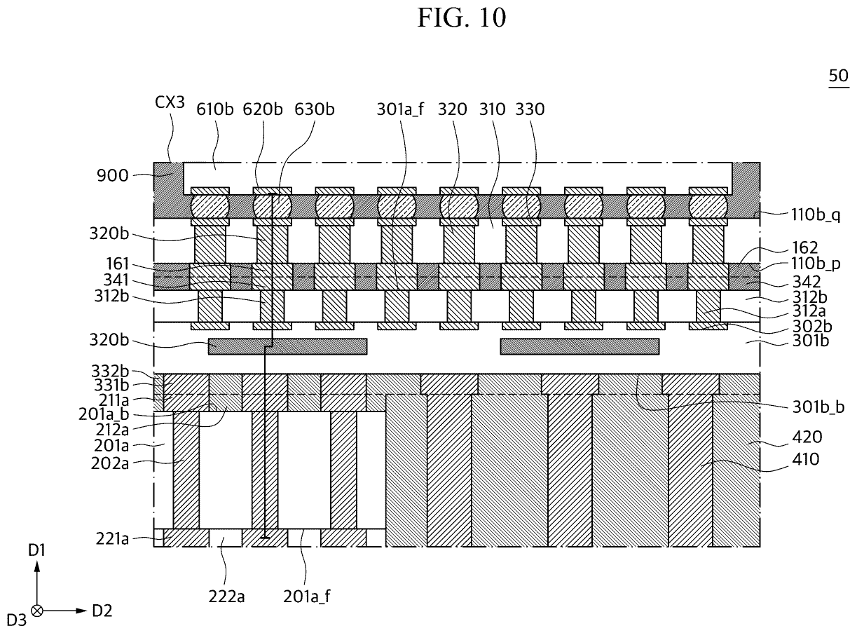

FIG. 9 is a cross-sectional view illustrating a semiconductor package 50 according to another example embodiment. FIG. 10 is an enlarged view of the portion indicated as “CX3” in FIG. 9. The cross-sectional view of semiconductor package 50 illustrated in FIG. 9 corresponds to the cross-sectional view of the semiconductor package 10 along the A-A′ cross-section illustrated in FIG. 2.

The semiconductor package 50 illustrated in FIG. 9 and FIG. 10 is substantially identical or similar to the semiconductor package 40 illustrated in FIG. 7 and FIG. 8, except that an interposer 100b and a second semiconductor chip 300b are bonded using hybrid bonding method. Below, the differences from the semiconductor package 40 illustrated in FIG. 7 and FIG. 8 are mainly explained. The differences are explained with reference to FIG. 1 to FIG. 4 to help understanding.

According to an example embodiment, the interposer 100b may include an interposer substrate 110b, an interposer through electrode 120b, an interposer pad 130b, a first middle bonding pad 161, and a first middle bonding insulation layer 162. The interposer substrate 110b, the interposer through electrode 120b, and the interposer pad 130b illustrated in FIG. 9 and FIG. 10 are substantially identical to the interposer substrate 110, the interposer through electrode 120, and the interposer pad 130 illustrated in FIG. 1 to FIG. 4, and thus detailed descriptions are omitted.

According to an example embodiment, the plurality of first middle bonding pads 161 and the first middle bonding insulation layer 162 may be arranged on a first surface 110b_p opposite to a second surface 110b_q of the interposer substrate 110b. Each of the plurality of first middle bonding pads 161 may be arranged corresponding to a plurality of interposer through electrodes 120b. The upper surface of the plurality of first middle bonding pads 161 may be connected to the lower surface of the plurality of interposer through electrodes 120b. The first middle bonding insulation layer 162 may surround the plurality of first middle bonding pads 161 on the first surface 110b_p of the interposer substrate 110b. According to an example embodiment, the outermost side surface of the first middle bonding insulation layer 162 may be aligned with the side surface of the interposer substrate 110b.

According to an example embodiment, the second semiconductor chip 300b may be placed on the back side 201a_b of the first semiconductor substrate 201a. The second semiconductor chip 300b may include a second semiconductor substrate 301b, a second front side pad 302b, a second front side insulation layer 311b, a second through electrode 312b, a second bonding pad 331b, a passive device 320b, a second bonding insulation layer 332b, a second middle bonding pad 341, and a second middle bonding insulation layer 342. The second semiconductor substrate 301b, the second front side pad 302b, the second front side insulation layer 311b, the second through electrode 312b, the second bonding pad 331b, the passive device 320b and the second bonding insulation layer 332b are substantially identical to the second semiconductor substrate 301a, the second front side pad 302a, the second front side insulation layer 311a, the second through electrode 312a, the second bonding pad 331a, the passive device 320a, and the second bonding insulation layer 332a illustrated in FIG. 7 and FIG. 8. Thus, detailed descriptions are omitted.

According to an example embodiment, the first middle bonding pad 161 of the interposer 100b and the second middle bonding pad 341 of the second semiconductor chip 300b may be directly bonded to each other by the metal-metal bonding method. Therefore, between the interposer 100b and the second semiconductor chip 300b, the first middle bonding pad 161 and the second middle bonding pad 341 may be bonded to each other by the Cu—Cu hybrid bonding method. The direct bonding between the first middle bonding pad 161 and the second middle bonding pad 341 as shown in FIG. 9 and FIG. 10 may be a bonding method substantially the same as the direct bonding between the first bonding pad 211 and the second bonding pad 331 described with reference to FIG. 1 to FIG. 4.

According to an example embodiment, the first middle bonding insulation layer 162 of the interposer 100b and the second middle bonding insulation layer 342 of the second semiconductor chip 300b may be directly bonded to each other by the dielectric-dielectric bonding method. The first middle bonding insulation layer 162 and the second middle bonding insulation layer 342 may form a bonding structure by including the same insulating material. The first middle bonding insulation layer 162 and the second middle bonding insulation layer 342 may be bonded to each other by a high-temperature annealing process while in contact with each other. Here, the bonding structure may have a stronger bonding strength due to the covalent bonding.

According to an example embodiment, the wafer-to-wafer bonding between the interposer 100b and the second semiconductor chip 300b may be implemented through the metal-metal bonding method between the first middle bonding pad 161 and the second middle bonding pad 341, and the dielectric-dielectric bonding method between the first middle bonding insulation layer 162 and the second middle bonding insulation layer 342. When the interposer 100b and the second semiconductor chip 300b are bonded using a hybrid bonding method, the electrical connection distance between the memory chip structure (the first memory chip structure 600a and the second memory chip structure 600b) on the interposer 100b and the passive device 320b in the second semiconductor chip 300b may be shortened. As the electrical connection distance between the memory chip structure (the first memory chip structure 600a and the second memory chip structure 600b) and the passive device 320b is shortened, parasitic resistance or parasitic inductance between the memory chip structure (the first memory chip structure 600a and the second memory chip structure 600b) and the second semiconductor chip 300b may be eliminated. Thus, the signal transmission speed and power efficiency between the memory chip structure (the first memory chip structure 600a and the second memory chip structure 600b) and the second semiconductor chip 300b may be improved. As illustrated in FIG. 10, through the structure of the semiconductor package 50, an electrical signal path connecting the memory chip structure (the first memory chip structure 600a and the second memory chip structure 600b)—the interposer 100b—the second semiconductor chip 300b—the first semiconductor chip 200a may be implemented.

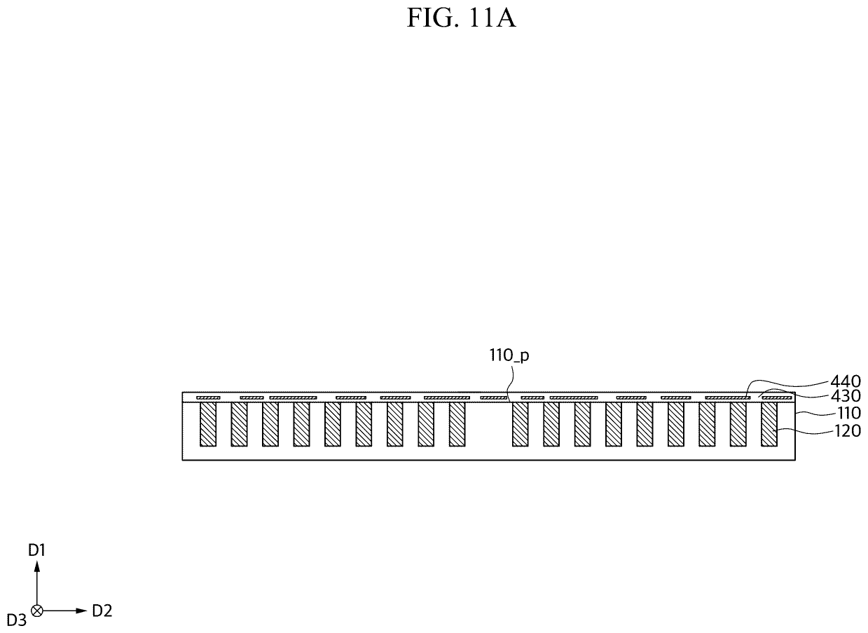

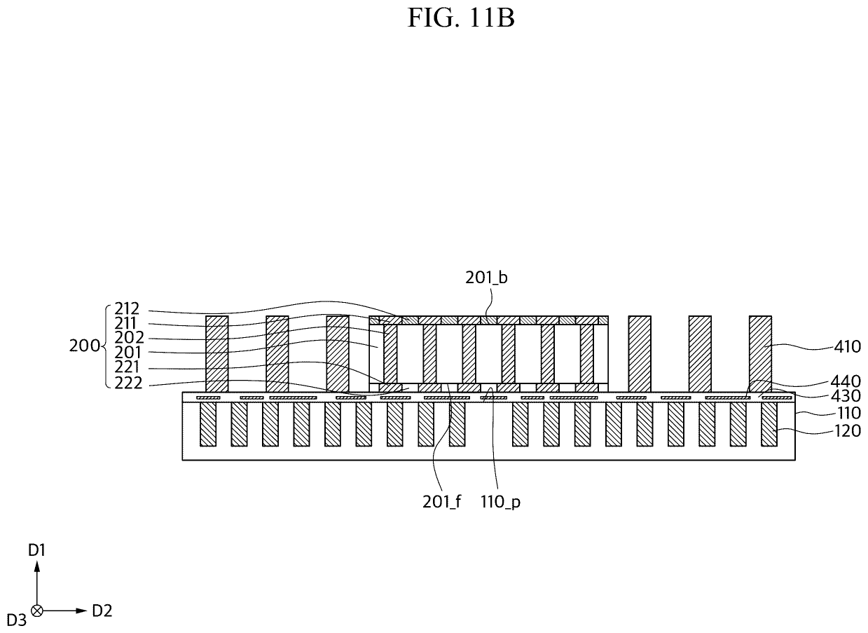

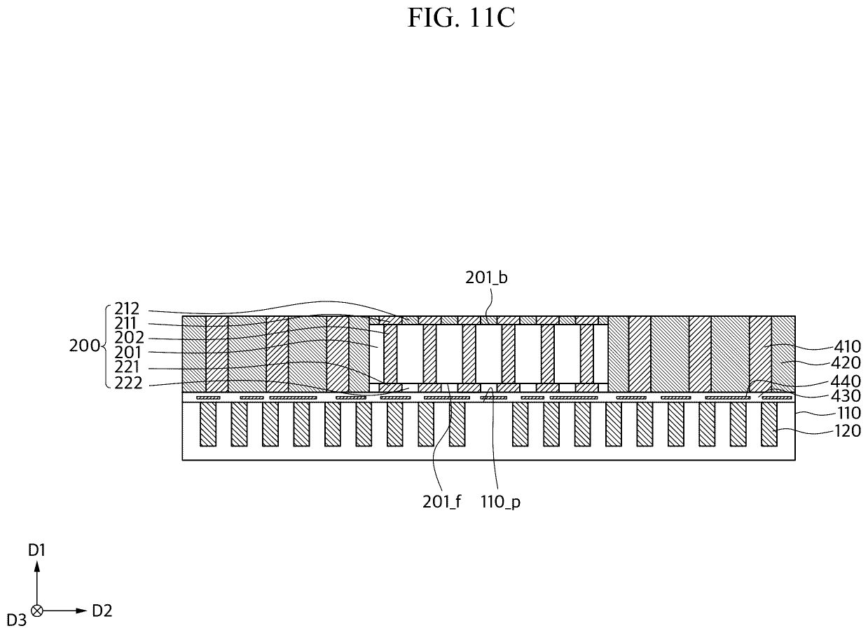

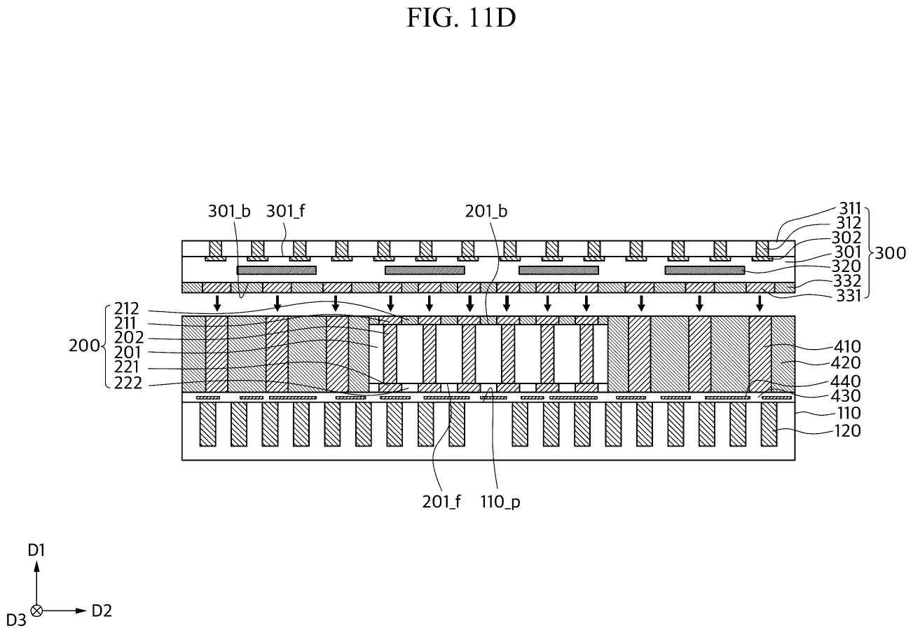

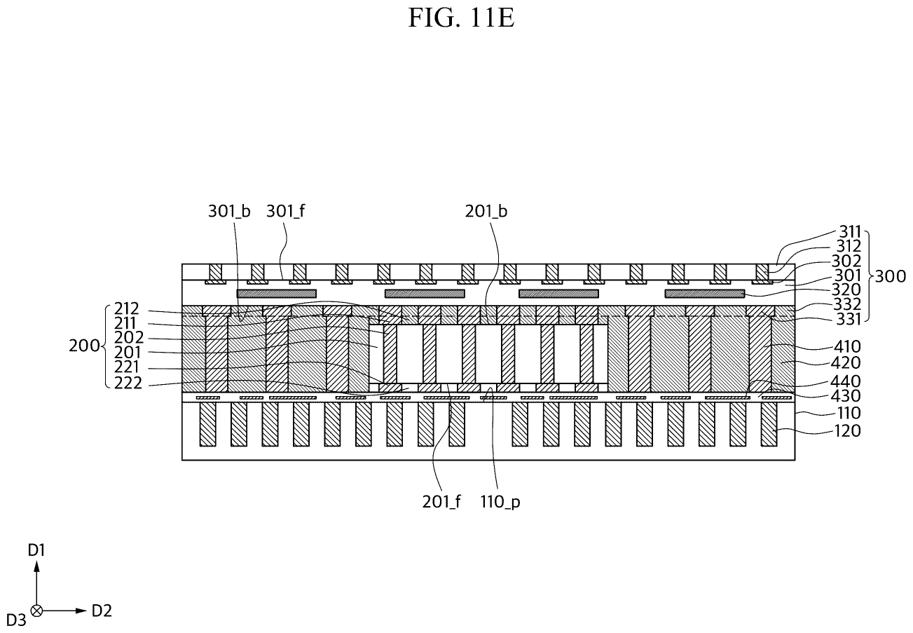

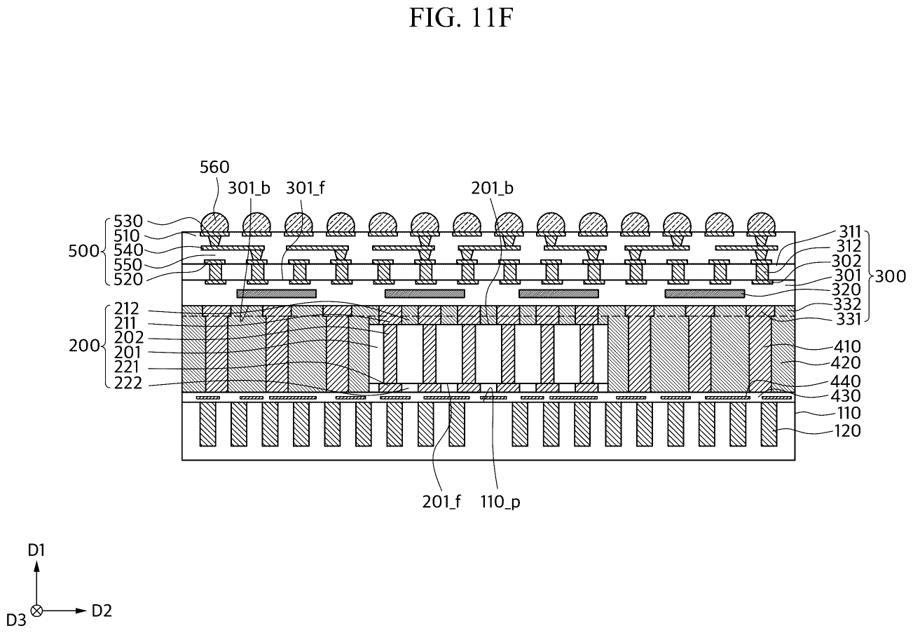

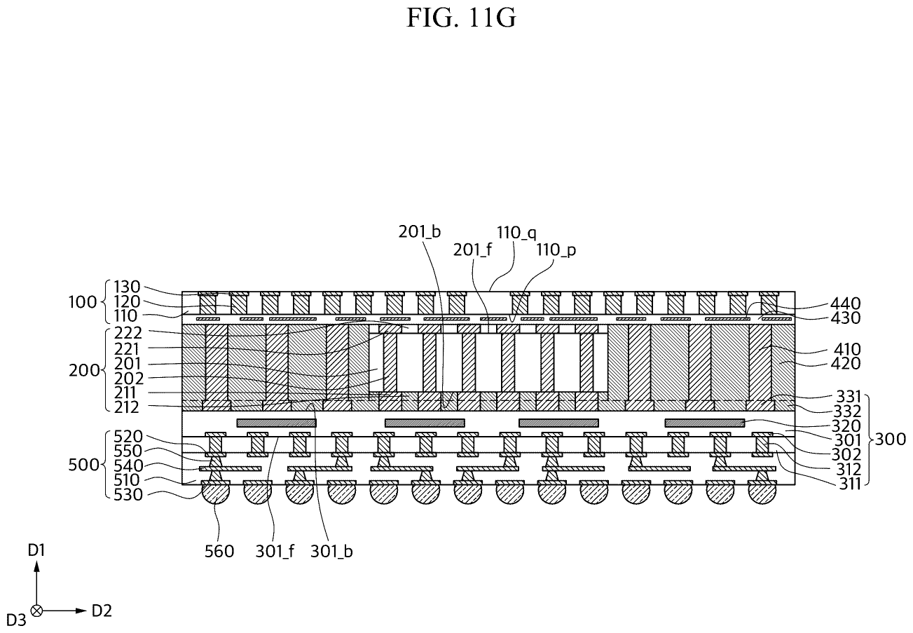

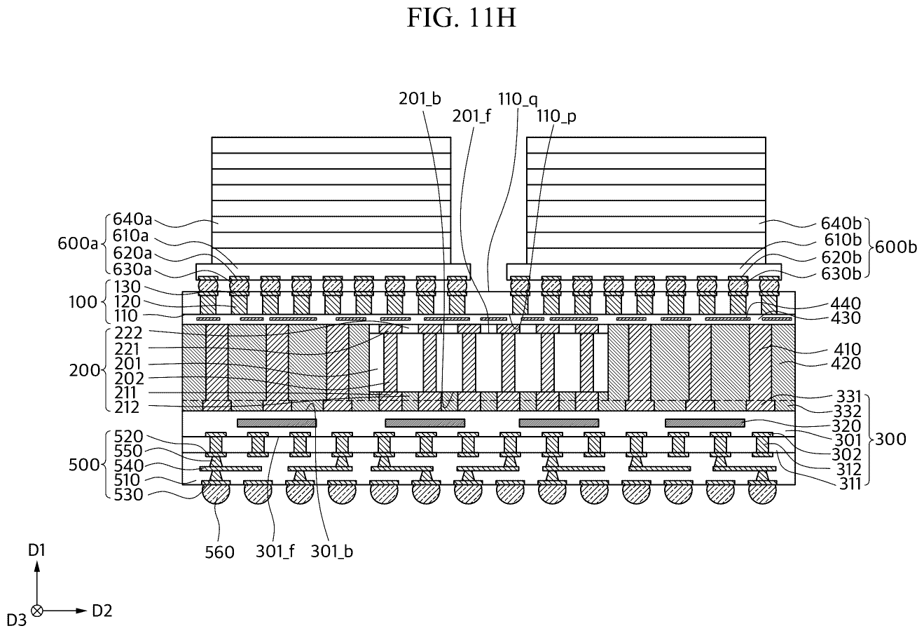

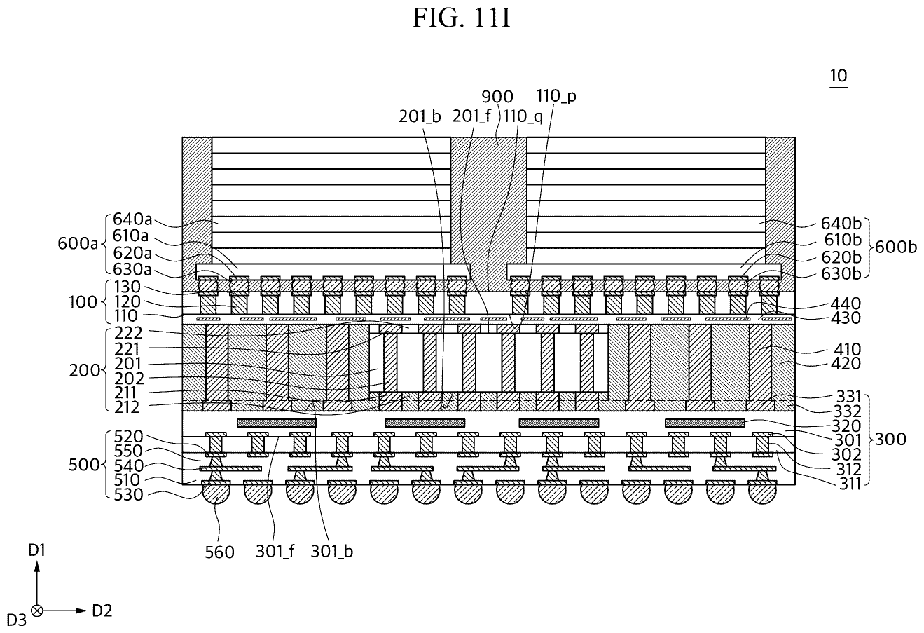

FIG. 11A to FIG. 11I are cross-sectional views illustrating a process sequence for explaining a method of manufacturing the semiconductor package 10 according to an example embodiment.

Referring to FIG. 11A, the interposer substrate 110 and the bonding film 430 positioned on the first surface 110_p of the interposer substrate 110 may be provided. The plurality of interposer through electrodes 120 may be embedded within the interposer substrate 110. The plurality of interposer through electrodes 120 may extend in the first direction D1 within the interposer substrate 110. Surfaces intersecting the first direction D1 of the plurality of interposer through electrodes 120 may be positioned to be coplanar with the first surface 110_p of the interposer substrate 110. However, the other surfaces to the surfaces of the plurality of interposer through electrodes 120 may be embedded within the interposer substrate 110 and not exposed.

According to an example embodiment, the bonding film 430 may be composed of a material having adhesive properties. The bonding film 430 may extend along the first surface 110_p of the interposer substrate 110. The conductive pattern 440 may be provided within the bonding film 430 and configured to be electrically connected to the plurality of interposer through electrodes 120. Even though FIG. 11A illustrates that the conductive pattern 440 is a pattern embedded in the bonding film 430, the conductive pattern 440 may be a conductive pad surrounded by the bonding film 430 according to an example embodiment. When the conductive pattern 440 is a conductive pad, the lower surface of the conductive pattern 440 may be exposed to the lower surface of the bonding film 430, and the upper surface of the conductive pattern 440 may be exposed to the upper surface of the bonding film 430.

Referring to FIG. 11B, the first semiconductor chip 200 may be mounted on the first surface 110_p of the interposer substrate 110. The first semiconductor chip 200 may include the first semiconductor substrate 201, the first through electrode 202, the first bonding pad 211, the first bonding insulation layer 212, the first front side pad 221, and the first front side insulation layer 222.

According to an example embodiment, the first semiconductor substrate 201 may form the body of the first semiconductor chip 200. The plurality of first through electrodes 202 may penetrate the first semiconductor substrate 201 in the first direction D1 and extend from the front side 201_f to the back side 201_b of the first semiconductor substrate 201. The plurality of first through electrodes 202 may be arranged spaced apart in the second direction D2 and/or the third direction D3.

According to an example embodiment, on the back side 201_b of the first semiconductor substrate 201, the plurality of first bonding pads 211 may be arranged to correspond to and be connected to each of the plurality of first through electrodes 202. The first bonding insulation layer 212 may surround a plurality of first bonding pads 211 on the back side 201_b of the first semiconductor substrate 201, and the outermost side surface of the first bonding insulation layer 212 may be aligned with the side surface of the first semiconductor substrate 201.

According to an example embodiment, on the front side 201_f of the first semiconductor substrate 201, the plurality of first front side pads 221 may be arranged to correspond to and be connected to each of the plurality of first through electrodes 202. Each of the plurality of first front side pads 221 may be electrically connected to the conductive pattern 440. The first front side insulation layer 222 may surround the plurality of first front side pads 221 on the front side 201_f of the first semiconductor substrate 201, and the outermost side surface of the first front side insulation layer 222 may be aligned with the side surface of the first semiconductor substrate 201. The first front side insulation layer 222 may be in contact with at least a portion of the bonding film 430.

According to an example embodiment, the plurality of conductive posts 410 arranged around the first semiconductor chip 200 may be formed on the bonding film 430. Each of the plurality of conductive posts 410 may be arranged to be in contact with the conductive pattern 440 so as to be electrically connected to the conductive pattern 440. The upper surface of each of the plurality of conductive posts 410 may be formed to be substantially coplanar with the upper surface of the first bonding pad 211.

Referring to FIG. 11C, the first molding layer 420 configured to seal the plurality of conductive posts 410 and the first semiconductor chip 200 may be formed on the first surface 110_p of the interposer substrate 110. The side surface of the first molding layer 420 may be formed to align with the side surface of the interposer substrate 110. The upper surface of the first molding layer 420 may be formed to be coplanar with the upper surface of each of the plurality of conductive posts 410, upper surfaces of the plurality of first bonding pads 211, and the upper surface of the first bonding insulation layer 212. According to an example embodiment, in order for the upper surface of the first molding layer 420 to be coplanar with the upper surfaces of the plurality of conductive posts 410, additional polishing processes may be performed on the first molding layer 420.

Referring to FIG. 11D and FIG. 11E, the second semiconductor chip 300 may be bonded to the first semiconductor chip 200 by wafer-to-wafer bonding. By heat and/or pressure being applied in the process of positioning the second semiconductor chip 300 on the first semiconductor chip 200, the plurality of first bonding pads 211 and a bonding pad (for example, a pad corresponding to the center bonding pad 331_C shown in FIG. 3) located at the center among the plurality of second bonding pads 331 are bonded, and a first bonding insulation layer 212 and a center area (for example, the area corresponding to the center bonding area 332_C shown in FIG. 3) of the second bonding insulation layer 332 may be bonded. Further, a bonding pad located on the outer side of the second bonding insulation layer 332 (for example, a pad corresponding to the outer bonding pad 331_O illustrated in FIG. 3) may be bonded to the conductive post 410.

In some example embodiments, the second bonding insulation layer 332 and the first bonding insulation layer 212 may be bonded by the covalent bonding. Further, the outer area of the second bonding insulation layer 332 (for example, the area corresponding to the outer bonding area 332_O illustrated in FIG. 3) and the first molding layer 420 may be bonded by the covalent bonding. For example, heat of the first temperature may be applied in the process of positioning a pad located at the center of the second bonding insulation layer 332b and the plurality of second bonding pads 331 on the first semiconductor chip 200, and in the process of positioning a pad located on the outer surface of the second bonding insulation layer 332b and a plurality of second bonding pads 331 on the first molding layer 420.

After then, by applying heat at a second temperature higher than the first temperature, the first bonding insulation layer 212 and the second bonding insulation layer 332, and the first bonding insulation layer 212 and the first molding layer 420 may be bonded to each other to form a single body. By the covalent bonding, the second bonding insulation layer 332 may form an integral body without forming an interface with the first bonding insulation layer 212 and the first molding layer 420.

According to an example embodiment, the first bonding pad 211 and the conductive post 410, which correspond to each other, may be expanded by heat and come into contact with the second bonding pad 331, and then may be diffusion bonded to form a single body through diffusion of the metal atoms included therein. By the diffusion bonding, the second bonding pad 331 may form an integral body without forming an interface with the first bonding pad 211 and the conductive post 410. The bond formed by the second bonding pad 331 with the first bonding pad 211 and the conductive post 410 may be the metal-metal bonding.

Referring to FIG. 11F, the redistribution structure 500 may be formed on the first surface 110_p of the interposer substrate 110.

According to an example embodiment, the redistribution structure 500 may be formed to include the redistribution insulation layer 510, the first redistribution pad 520, the second redistribution pad 530, the redistribution pattern 540, and the redistribution via 550. In the example embodiment, even though it is illustrated that the plurality of redistribution patterns 540 are spaced in the second direction D2 and/or the third direction D3 on the same plane, the present disclosure is not limited thereto. The plurality of redistribution patterns 540 may be formed into a multi-layer structure by varying the level along the first direction D1. The first redistribution pad 520 may be formed to contact and be electrically connected to the second through electrode 312. The second redistribution pad 530 may be formed so that its upper surface is exposed to the outside.

According to an example embodiment, after forming the redistribution structure 500, the external connecting terminals 560 may be attached to each second redistribution pad 530.

Referring to FIG. 11G, after turning over the resulting FIG. 11F, the top of the interposer substrate 110 may be ground and/or polished. After then, the interposer pad 130 may be formed on top of the interposer through electrode 120. According to an example embodiment, after forming the interposer pad 130, through the deposition of insulating material and additional polishing processes, the upper surface of the interposer pad 130 and the second surface 110_q of the interposer substrate 110 may be formed to form the same plane. Further, according to another example embodiment, unlike what is illustrated in FIG. 11G, the interposer pad 130 may be formed to protrude in the first direction D1 from the second surface 110_q of the interposer substrate 110.

Referring to FIG. 11H, a pair of memory chip structures (the first memory chip structure 600a and the second memory chip structure 600b) may be mounted on the second surface 110_q of the interposer substrate 110. According to an example embodiment, after the first connecting terminal 630a and the second connecting terminal 630b of a pair of memory chip structures (the first memory chip structure 600a and the second memory chip structure 600b) are attached to the interposer pad 130, the first connecting terminal 630a and the second connecting terminal 630b may be electrically connected to the interposer pad 130.

Referring to FIG. 11I, the second molding layer 900 may be formed on the second surface 110_q of the interposer substrate 110 to seal a pair of memory chip structures (the first memory chip structure 600a and the second memory chip structure 600b). The second molding layer 900 may cover the side surfaces of one pair of memory chip structures (the first memory chip structure 600a and the second memory chip structure 600b), and at the same time, the second molding layer 900 may fill the space between a plurality of first connecting terminals 630a and between the second connecting terminals 630b. The side surface of the second molding layer 900 may be formed to align with the side surface of the interposer substrate 110. After the second molding layer 900 is formed, the upper part of the second molding layer 900 may be polished in order for the upper surface of the second molding layer 900 to be coplanar with the upper surfaces of one pair of memory chip structures (the first memory chip structure 600a and the second memory chip structure 600b). When the second molding layer 900 is formed to seal one pair of memory chip structures (the first memory chip structure 600a and the second memory chip structure 600b), the semiconductor package 10 according to the example embodiment is completed.

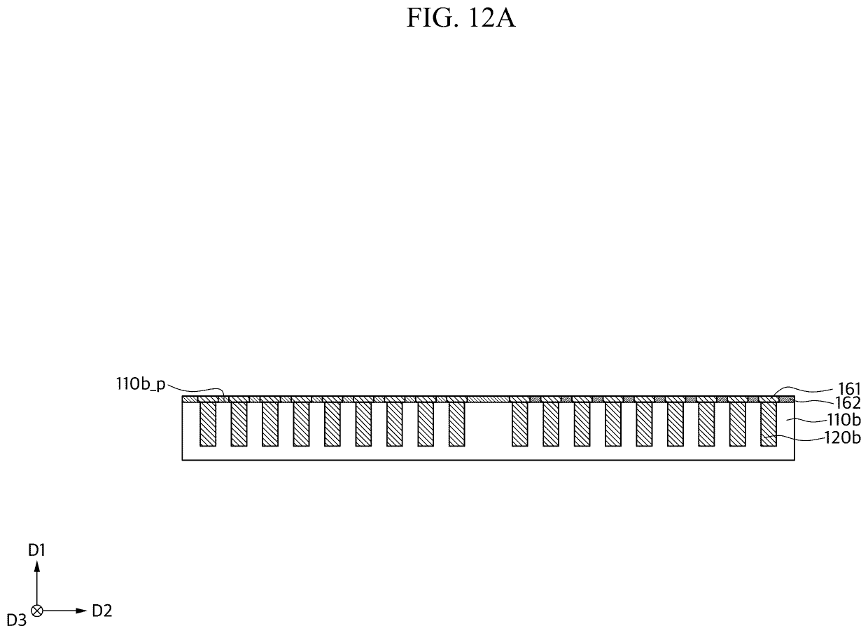

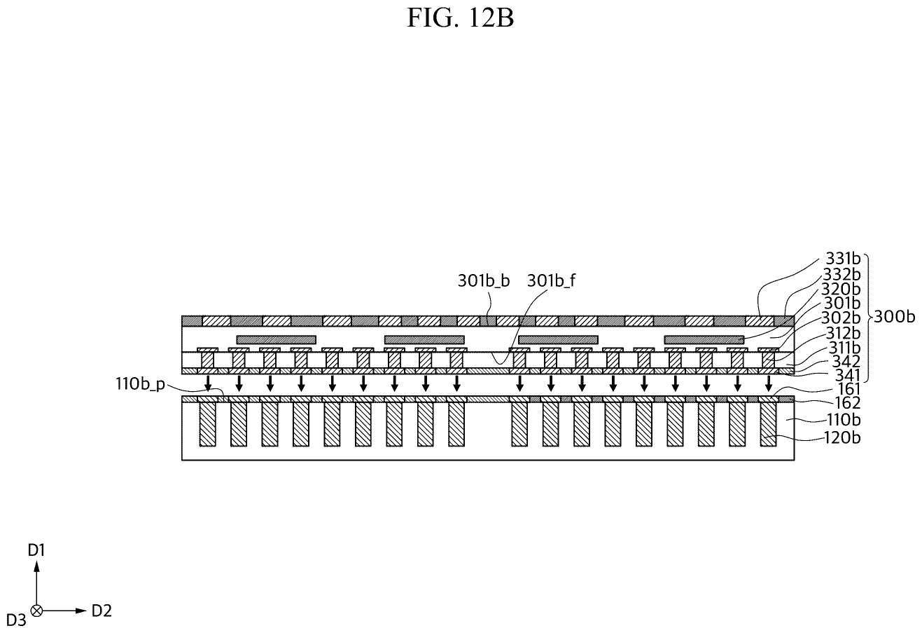

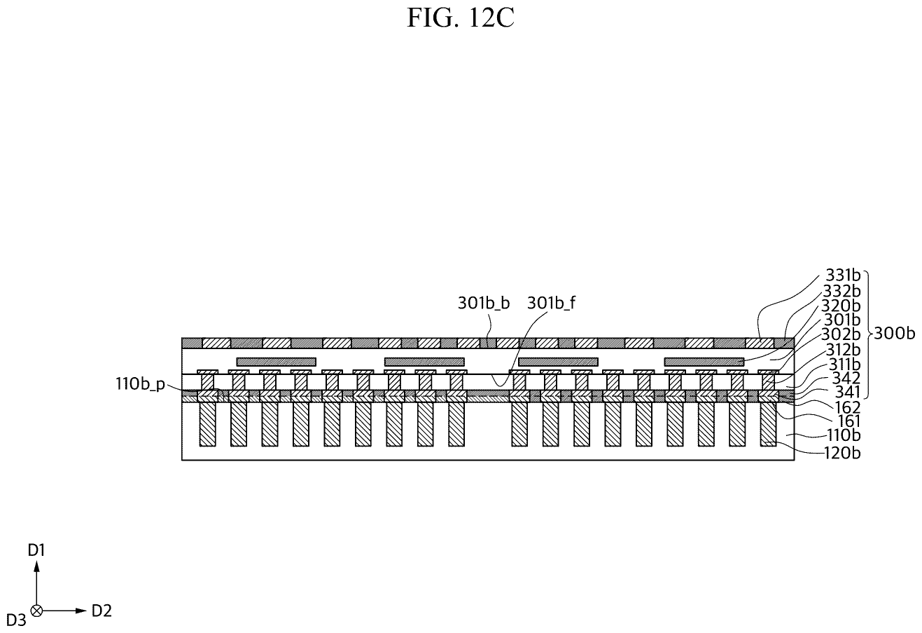

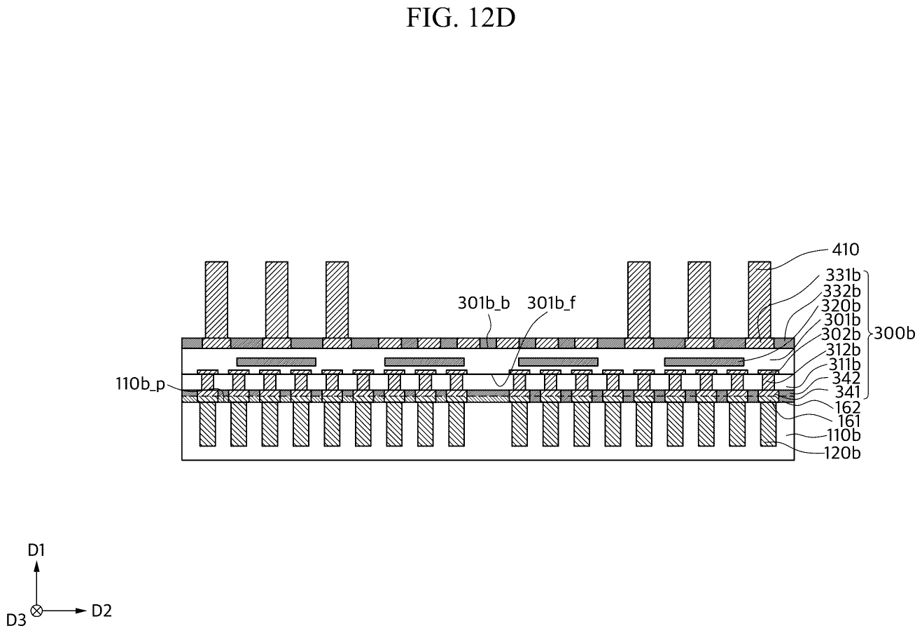

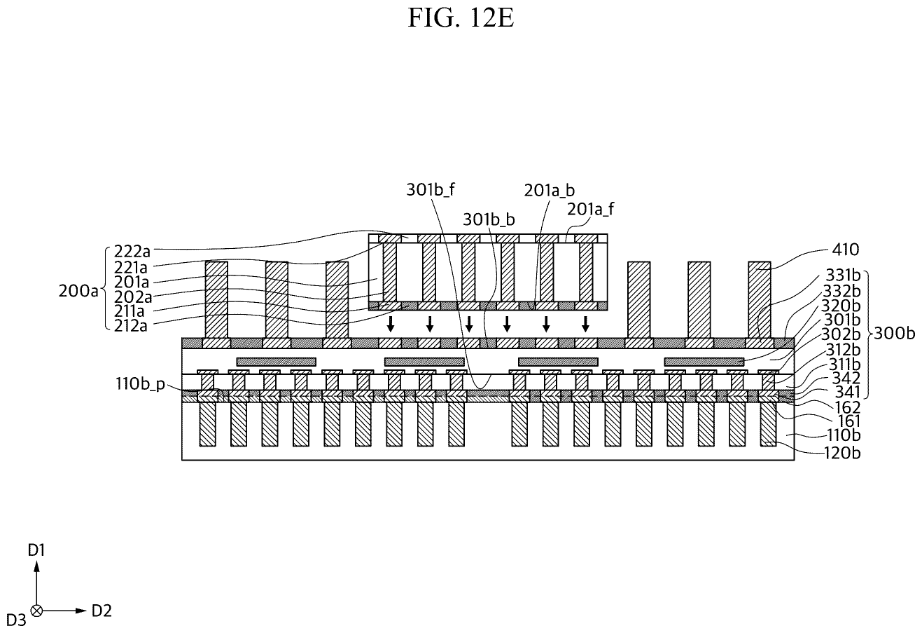

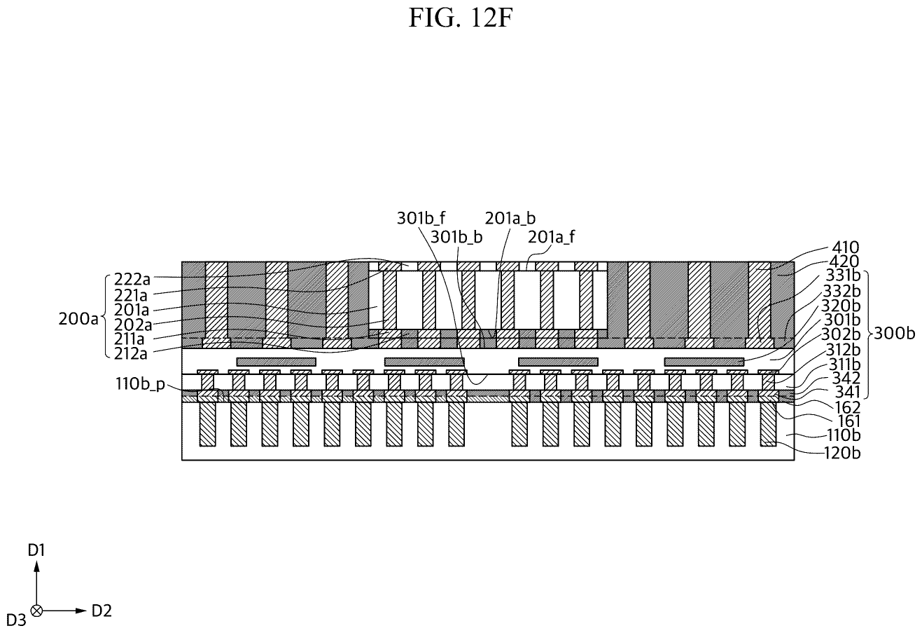

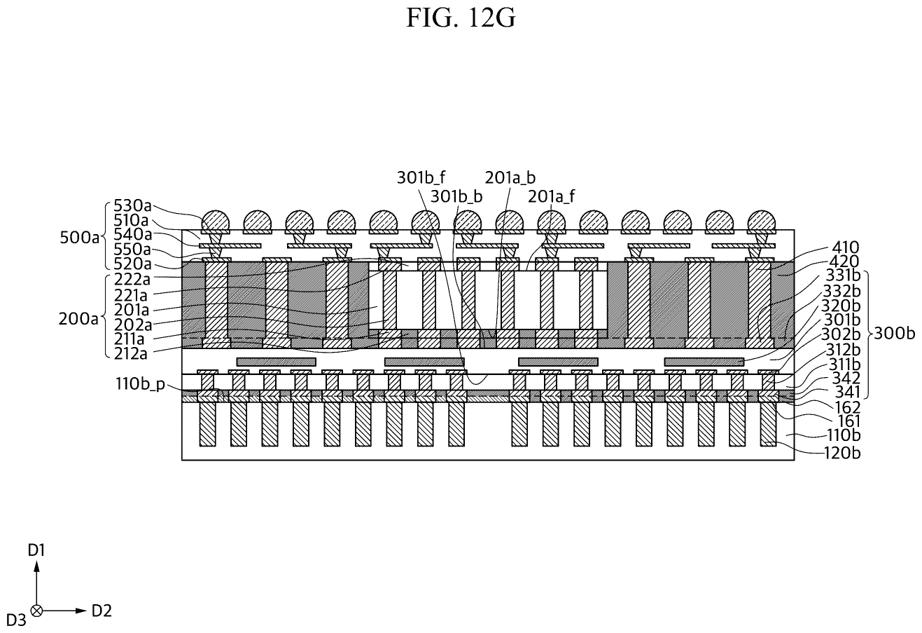

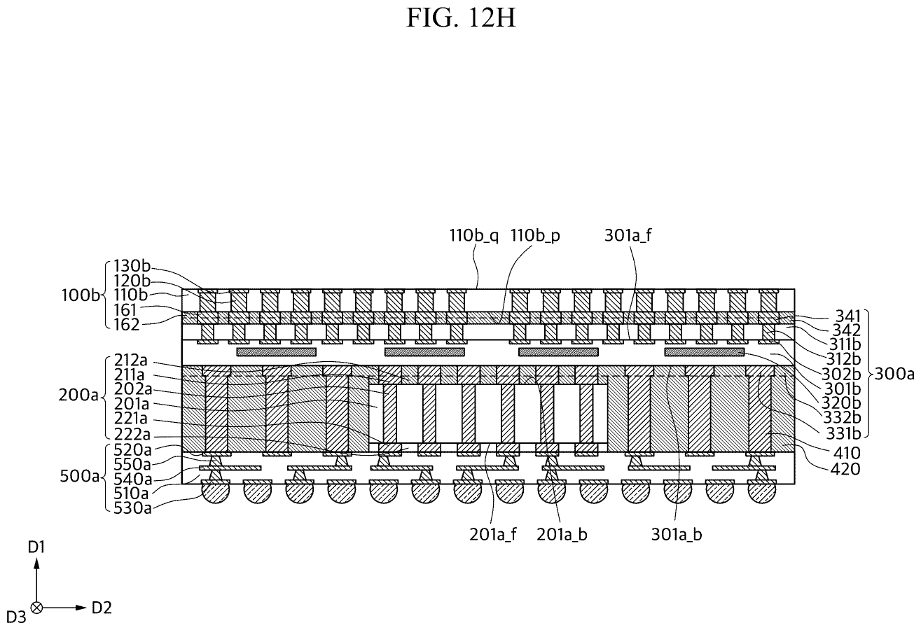

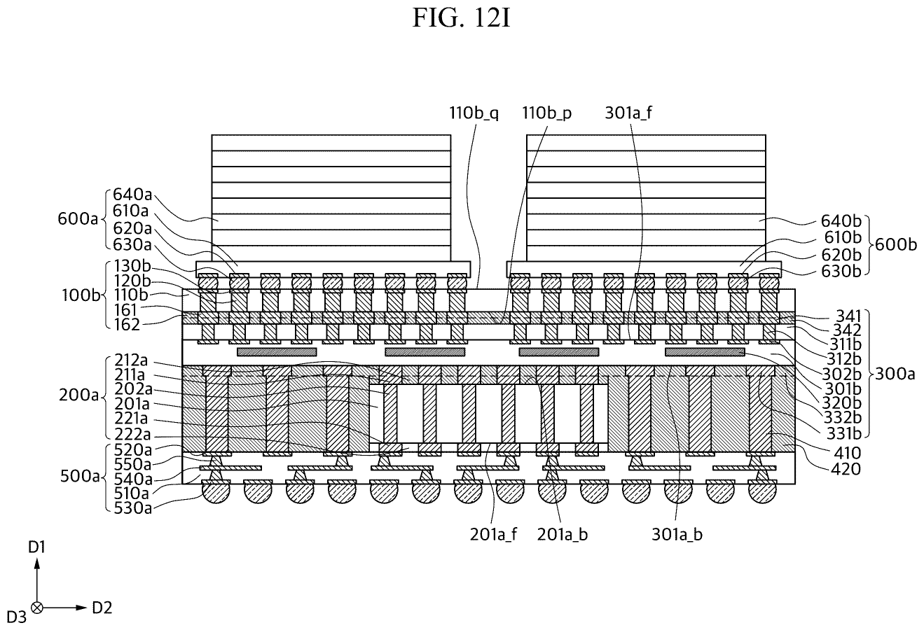

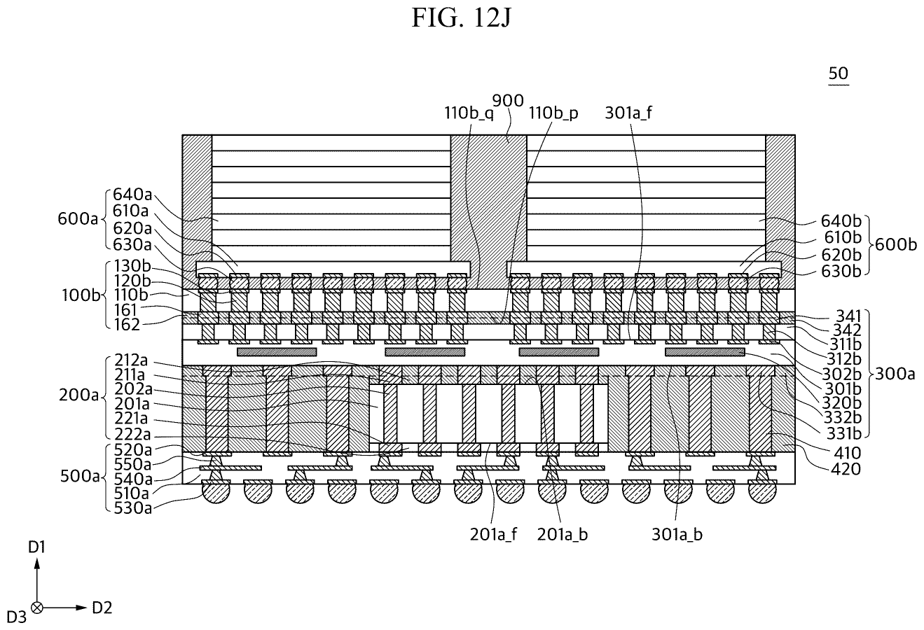

FIG. 12A to FIG. 12J are cross-sectional views illustrating a process sequence for explaining a method of manufacturing a semiconductor package 50 according to an example embodiment.

The contents already described with reference to FIG. 11A to FIG. 11J in the description of FIG. 12A to FIG. 12J are briefly explained, or omitted.

Referring to FIG. 12A, provided may be the first middle bonding pad 161 and the first middle bonding insulation layer 162 positioned on the interposer substrate 110b and the first surface 110b_p of the interposer substrate 110b. The plurality of interposer through electrodes 120b may be embedded within the interposer substrate 110b.

According to an example embodiment, the first middle bonding pad 161 may be arranged to be in contact with and electrically connected to the interposer through electrode 120b. The first middle bonding insulation layer 162 may surround the first middle bonding pad 161 on the first surface 110b_p of the interposer substrate 110b. Further, the upper surface of the first middle bonding insulation layer 162 may be formed to be coplanar with the upper surface of the first middle bonding pad 161.

Referring to FIG. 12B and FIG. 12C, the second semiconductor chip 300b may be wafer-to-wafer bonded on the interposer substrate 110b. The second middle bonding pad 341 and the second middle bonding insulation layer 342 may be provided on the lower surface of the second front side insulation layer 311b of the second semiconductor chip 300b.

According to an example embodiment, by heat and/or pressure being applied in the process of positioning the second semiconductor chip 300b on the interposer substrate 110b, some of the plurality of first middle bonding pads 161 and a plurality of second middle bonding pads 341 of a second semiconductor chip may be bonded and the first middle bonding insulation layer 162 and the second middle bonding insulation layer 342 may be bonded. In some example embodiments, the first middle bonding insulation layer 162 and the second middle bonding insulation layer 342 may be bonded by the covalent bonding. For example, heat of the first temperature may be applied in the process of positioning the second middle bonding insulation layer 342 on the first middle bonding insulation layer 162.

After then, by applying heat at a second temperature higher than the first temperature, the first middle bonding insulation layer 162 and the second middle bonding insulation layer 342 may be bonded to each other to form a single body. By the covalent bonding, the first middle bonding insulation layer 162 and the second middle bonding insulation layer 342 may form a single body without forming an interface. The bonding between the first middle bonding insulation layer 162 and the second middle bonding insulation layer 342 may be dielectric-dielectric bonding.

According to an example embodiment, the first middle bonding pad 161 and the second middle bonding pad 341, which correspond to each other, may be expanded by heat and brought into contact with each other, and then may be diffusion bonded to form a single unit through diffusion of the metal atoms they contain. By the diffusion bonding, the first middle bonding pad 161 and the second middle bonding pad 341 may form a single body without forming an interface. The bonding between the first middle bonding pad 161 and the second middle bonding pad 341 may be the metal-metal bonding.

Referring to FIG. 12D, the conductive post 410 may be formed on the outer bonding pad 331_O located on the outer side of the second bonding pad 331b of the second semiconductor chip 300b. According to an example embodiment, the conductive post 410 may be formed integrally with the outer bonding pad 331_O. In another example embodiment, the conductive post 410 may be formed without forming an interface with the second bonding pad 331b.

Referring to FIG. 12E and FIG. 12F, the first semiconductor chip 200a may be wafer-to-wafer bonded to the second semiconductor chip 300b. By heat and/or pressure being applied in the process of positioning the first semiconductor chip 200a on the second semiconductor chip 300b, a bonding pad at the center among the plurality of first bonding pads 211a and a bonding pad at the center among the plurality of second bonding pads 331b are bonded, and a center area of the first bonding insulation layer 212a and a center area of the second bonding insulation layer 332b may be bonded. In some example embodiments, the center area of the second bonding insulation layer 332b and the first bonding insulation layer 212a may be bonded by the covalent bonding. Further, the outer area of the second bonding insulation layer 332b and the first molding layer 420 may be combined by the covalent bonding. For example, heat of the first temperature may be applied in the process of positioning the first bonding insulation layer 212a on the center area of the second bonding insulation layer 332b, in the process of positioning the first bonding pad 211a on the bonding pad located at the center among the plurality of second bonding pads 331b, and in the process of positioning the first molding layer 420 on the outer area of the second bonding insulation layer 332b.

After then, by applying heat at a second temperature higher than the first temperature, the second bonding insulation layer 332b may be bonded to the first bonding insulation layer 212a and the first molding layer 420 to form an integral body. By the covalent bonding, the second bonding insulation layer 332b may form an integral body without forming an interface with the first bonding insulation layer 212a and the first molding layer 420.

According to an example embodiment, the first bonding pad 211a and the second bonding pad 331b, which correspond to each other, may expand by heat and come into contact with each other, and then may be diffusion bonded to form a single unit through diffusion of the metal atoms they contain. By the diffusion bonding, the second bonding pad 331b and the first bonding pad 211a may form a single body without forming an interface. Likewise, the conductive post 410 and the second bonding pad 331b may be diffusion bonded to each other. The bond formed by the second bonding pad 331b with the first bonding pad 211a and the conductive post 410 may be the metal-metal bonding.

Referring to FIG. 12G, the redistribution structure 500a may be formed on the front side 201a_f of the first semiconductor substrate 201a. Here, the first redistribution pad 520a of the redistribution structure 500a may be formed to be connected to the conductive post 410 and the first front side pad 221a of the first semiconductor chip 200a. After forming the redistribution structure 500a, the external connecting terminal 560 may be attached to each second redistribution pad 530a.

The process of forming the redistribution structure 500a and the external connecting terminal 560 overlaps with the description made with reference to FIG. 11F, and thus detailed description is omitted.

Sequentially referring to FIG. 12H, FIG. 12I, and FIG. 12J, after flipping the resulting FIG. 12G, the top of the interposer substrate 110b may be ground and/or polished. After then, the interposer pad 130b may be formed on top of the interposer through electrode 120. After then, a pair of memory chip structures (the first memory chip structure 600a and the second memory chip structure 600b) may be mounted on a second surface 110b_q of the interposer substrate 110b. After then, the second molding layer 900 may be formed to seal a pair of memory chip structures (the first memory chip structure 600a and the second memory chip structure 600b). When the second molding layer 900 is formed to seal a pair of memory chip structures (the first memory chip structure 600a and the second memory chip structure 600b), the semiconductor package 50 according to this example embodiment is completed. The series of operations in FIG. 12H, FIG. 12I, and FIG. 12J overlap with those described with reference to FIG. 11G, FIG. 11H, and FIG. 11I, and thus detailed descriptions are omitted below.

As described above, example embodiments are disclosed with respect to the drawings in the present disclosure. In the present disclosure, the example embodiments are described using specific terms, but the terms are used solely for the purpose of explaining the technical ideas of the present disclosure and are not intended to limit the meaning or scope of the present disclosure as set forth in the claims. Therefore, those skilled in the art will understand that various modifications and equivalent example embodiments are possible from this.

What is claimed is:

1. A semiconductor package comprising:
an interposer comprising a first surface and a second surface opposite to the first surface;
a first semiconductor chip comprising:
a first semiconductor substrate comprising a front side facing the first surface of the interposer in a first direction,
a plurality of first bonding pads on a back side that is opposite to the front side of the first semiconductor substrate, and
a first bonding insulation layer surrounding the plurality of first bonding pads;
a second semiconductor chip comprising:
a second semiconductor substrate comprising a back side facing the back side of the first semiconductor substrate in the first direction,
a passive device that is included in the second semiconductor substrate and is electrically connected to the first semiconductor chip,
a plurality of second bonding pads on the back side of the second semiconductor substrate, and
a second bonding insulation layer surrounding the plurality of second bonding pads; and
a plurality of conductive posts that are placed on a side surface of the first semiconductor chip and extending to the back side of the second semiconductor substrate to connect the interposer and the second semiconductor chip,
wherein at least one of the plurality of first bonding pads and at least one of the plurality of second bonding pads are directly bonded to each other, and
a portion of the first bonding insulation layer and a portion of the second bonding insulation layer are directly bonded to each other.

2. The semiconductor package of claim 1, wherein the plurality of second bonding pads comprise:
a center bonding pad that is directly bonded to one of the plurality of first bonding pads; and
an outer bonding pad that is directly bonded to one of the plurality of conductive posts.

3. The semiconductor package of claim 1, further comprising a molding layer configured to seal the plurality of conductive posts and the first semiconductor chip between the interposer and the second semiconductor chip,
wherein the second bonding insulation layer comprises:
a center bonding area that is directly bonded to the first bonding insulation layer; and
an outer bonding area that is directly bonded to the molding layer.

4. The semiconductor package of claim 3, wherein the molding layer comprises a material that is identical to a material of the second bonding insulation layer.

5. The semiconductor package of claim 1, wherein a width of the second semiconductor chip in a second direction intersecting the first direction is greater than a width of the first semiconductor chip in the second direction.

6. The semiconductor package of claim 1, wherein the first semiconductor chip further comprises:
a plurality of first through electrodes that penetrate the first semiconductor substrate;
an upper pad that is placed on the first semiconductor substrate and is connected to each of the plurality of first through electrodes; and
an upper insulation layer surrounding the upper pad,
wherein an upper surface of the upper insulation layer is coplanar with an upper surface of one of the plurality of conductive posts.

7. The semiconductor package of claim 1, further comprising one pair of memory chip structures that are mounted on the second surface of the interposer and are spaced apart from each other in a second direction intersecting the first direction.

8. The semiconductor package of claim 7, wherein the interposer further comprises an interposer pattern extending in the second direction and is configured to electrically connect each of the one pair of memory chip structures.

9. The semiconductor package of claim 7, wherein the one pair of memory chip structures are high-bandwidth-memory (HBM).

10. The semiconductor package of claim 1, wherein an area of the second surface of the interposer is substantially identical to an area of a front side of the second semiconductor substrate.

11. A semiconductor package comprising:
an interposer comprising an interposer substrate comprising a first surface and a second surface opposite to the first surface;
a logic chip comprising:
a first semiconductor substrate that is spaced apart from the first surface of the interposer substrate and comprises a back side facing the interposer,
a first bonding pad on the back side of the first semiconductor substrate, and
a first bonding insulation layer surrounding the first bonding pad;
a passive device chip comprising:
a second semiconductor substrate comprising a back side facing the back side of the first semiconductor substrate in a first direction,
a passive device included in the second semiconductor substrate and is electrically connected with the logic chip, a second bonding pad on the back side of the second semiconductor substrate, and
a second bonding insulation layer surrounding the second bonding pad;
a redistribution structure disposed on a front side opposite to the back side of the first semiconductor substrate; and
a plurality of conductive posts placed on a side surface of the logic chip in the redistribution structure and are configured to connect the redistribution structure and the passive device chip,
wherein the first bonding pad is directly bonded to the second bonding pad, and the first bonding insulation layer is directly bonded to the second bonding insulation layer.

12. The semiconductor package of claim 11, wherein the logic chip further comprises a first through electrode that penetrates the first semiconductor substrate and is connected to the first bonding pad,
wherein an upper surface of the first bonding pad is coplanar with an upper surface of the conductive post.

13. The semiconductor package of claim 11, further comprising:
a conductive pattern that is placed between the interposer and the passive device chip, and is electrically connected to the interposer and the passive device chip; and
a bonding film surrounding the conductive pattern.

14. The semiconductor package of claim 13, wherein a side surface of the bonding film, a side surface of the interposer substrate and a side surface of the second semiconductor substrate are aligned with respect to each other.

15. The semiconductor package of claim 11, wherein the interposer further comprises:
a plurality of first middle bonding pads placed on the first surface of the interposer substrate; and
a first middle bonding insulation layer surrounding the plurality of first middle bonding pads,
wherein the passive device chip further comprises:
a plurality of second through electrodes placed on a front side of the second semiconductor substrate;
a plurality of second middle bonding pads connected to upper surfaces of the plurality of second through electrodes; and
a second middle bonding insulation layer surrounding the plurality of second middle bonding pads,
wherein at least one of the plurality of first middle bonding pads and at least one of the plurality of second middle bonding pads are directly bonded to each other, and the first middle bonding insulation layer and the second middle bonding insulation layer are directly bonded to each other.

16. The semiconductor package of claim 11, wherein the passive device, the first bonding pad and the second bonding pad are electrically connected to each other.

17. The semiconductor package of claim 11, further comprising a first molding layer that is placed between the redistribution structure and the passive device chip, the first molding layer configured to seal the logic chip and the plurality of conductive posts,
wherein a side surface of the first molding layer is aligned with a side surface of the interposer substrate and a side surface of the second semiconductor substrate.

18. The semiconductor package of claim 11, further comprising:
one pair of memory chip structures that are mounted on the second surface of the interposer and are spaced apart from each other in a second direction intersecting the first direction; and
a second molding layer configured to seal the one pair of memory chip structures,
wherein a side surface of the second molding layer is aligned with a side surface of the interposer substrate and a side surface of the second semiconductor substrate.

19. A semiconductor package comprising:
an interposer comprising an interposer substrate comprising a first surface and a second surface opposite to the first surface, and an interposer through electrode that penetrates the interposer substrate;
a logic chip comprising a first semiconductor substrate comprising a front side facing the first surface of the interposer in a first direction, a plurality of first bonding pads on a back side that is opposite to the front side of the first semiconductor substrate, and a first bonding insulation layer surrounding the plurality of first bonding pads;
a passive device chip comprising:
a second semiconductor substrate comprising a back side facing a back side of the first semiconductor substrate in the first direction,
a passive device included in the second semiconductor substrate and connected with the logic chip, a plurality of second bonding pads on the back side of the second semiconductor substrate, and
a second bonding insulation layer surrounding the plurality of second bonding pads;
a plurality of conductive posts that are placed on a side surface of the logic chip on the back side of the second semiconductor substrate to connect the interposer and the passive device chip;
one pair of stacked memory chip structures that are mounted on the second surface of the interposer and spaced apart from each other in a second direction intersecting the first direction;
a redistribution structure disposed on a front side opposite to the back side of the second semiconductor substrate;
a first molding layer configured to seal the passive device chip and the plurality of conductive posts between the redistribution structure and the passive device chip; and
a second molding layer configured to seal the one pair of stacked memory chip structures on the second surface of the interposer substrate,
wherein at least one of the plurality of first bonding pads and at least one of the plurality of second bonding pads are directly bonded to each other, and a portion of the first bonding insulation layer and a portion of the second bonding insulation layer are directly bonded to each other,
wherein a width of the second semiconductor substrate in the second direction is greater than a width of the first semiconductor substrate in the second direction and is equal to a width of the interposer substrate in the second direction.

20. The semiconductor package of claim 19, wherein the plurality of second bonding pads comprise:
a center bonding pad that is directly bonded to at least one of the plurality of first bonding pads; and
an outer bonding pad that is directly bonded to at least one of the plurality of conductive posts,
wherein the second bonding insulation layer comprises:
a center bonding area that is directly bonded to the first bonding insulation layer; and
an outer bonding area that is directly bonded to the first molding layer.
